(19) United States
(12) Patent Application Publication
(10) Pub. No.: US 2025/0079321 A1
(43) Pub. Date: Mar. 6, 2025

(54) Vertically Oriented Interposer Stack And Assembly

(71) Applicant: KYOCERA AVX Components Corporation, Fountain Inn, SC (US)

(72) Inventors: Jonathan Herr, Taylors, SC (US); Cory Nelson, Simpsonville, SC (US); Marianne Berolini, Greer, SC (US); Joseph Hock, Surfside Beach, SC (US)

(21) Appl. No.: 18/805,598

(22) Filed: Aug. 15, 2024

Related U.S. Application Data
(60) Provisional application No. 63/579,299, filed on Aug. 29, 2023.

(51) Int. Cl. H01L 23/538; H01L 23/00; H01L 23/48; H01L 25/00; H01L 25/065

(52) U.S. Cl. CPC H01L 23/5385; H01L 23/481; H01L 25/0655; H01L 25/50; H01L 24/08; H01L 2224/08225

(57) ABSTRACT

Vertically oriented interposer stacks, assemblies, and methods are provided. For example, a vertically oriented interposer stack includes a plurality of interposers and a plurality of components. Each component is disposed between adjacent interposers. Each interposer includes a first side surface opposite a second side surface along the vertical direction. The first side surface and the second side surface each extend along the longitudinal direction from a first end surface to a second end surface. Each interposer has a first external termination formed on the first side surface and a second external termination formed on the first side surface. The first and second external terminations are spaced apart along the longitudinal direction. The interposers are stacked along the lateral direction such that the first external terminations are generally aligned with one another along the lateral direction and the second external terminations are generally aligned with one another along the lateral direction.

### RELATED APPLICATION

The present application is based upon and claims priority to U.S. Provisional Patent Application Ser. No. 63/579,299, having a filing date of Aug. 29, 2023, which is incorporated herein by reference.

### BACKGROUND OF THE INVENTION

High frequency radio signal communication has increased in popularity. For example, the demand for increased data transmission speed for wireless connectivity has driven demand for high frequency components, including those configured to operate at high frequencies, including 5G spectrum frequencies. A trend towards miniaturization has also increased the desirability of small, passive components and generally decreased the power handling capacity of such components. Miniaturization has also increased the difficulty of surface mounting small, passive components. Thus, a more compact component bank would be welcomed in the art.

### SUMMARY OF THE INVENTION

In accordance with one embodiment of the present invention, a vertically oriented interposer stack defines a longitudinal direction, a lateral direction, and a vertical direction that are orthogonal to one another. The vertically oriented interposer stack includes a plurality of interposers and a plurality of components. Each interposer of the plurality of interposers includes a first side surface opposite a second side surface along the vertical direction and a first end surface opposite a second end surface along the longitudinal direction. The first side surface and the second side surface each extend along the longitudinal direction from the first end surface to the second end surface. Each component of the plurality of components is disposed between adjacent interposers. Each interposer of the plurality of interposer has a first external termination formed on the first side surface and a second external termination formed on the first side surface. The first external termination is spaced apart from the second external termination along the longitudinal direction. The plurality of interposers are stacked along the lateral direction such that the first external terminations of the plurality of interposers are generally aligned with one another along the lateral direction and the second external terminations of the plurality of interposers are generally aligned with one another along the lateral direction.

In accordance with another embodiment of the present invention, an assembly includes a device having a mounting surface and a vertically oriented interposer stack. The vertically oriented interposer stack defines a longitudinal direction, a lateral direction, and a vertical direction that are orthogonal to one another. The vertically oriented interposer stack includes a plurality of interposers and a plurality of components. Each interposer of the plurality of interposers includes a first side surface opposite a second side surface along the vertical direction and a first end surface opposite a second end surface along the longitudinal direction. The first side surface and the second side surface each extend along the longitudinal direction from the first end surface to the second end surface. Each component of the plurality of components is disposed between adjacent interposers. Each interposer of the plurality of interposer has a first external termination formed on the first side surface and a second external termination formed on the first side surface. The first external termination is spaced apart from the second external termination along the longitudinal direction. The plurality of interposers are stacked along the lateral direction such that the first external terminations of the plurality of interposers are generally aligned with one another along the lateral direction and the second external terminations of the plurality of interposers are generally aligned with one another along the lateral direction. The vertically oriented interposer stack is disposed on the mounting surface of the device along the first side surface such that the first external termination and the second external termination of each interposer of the plurality of interposers is in contact with the mounting surface.

In accordance with yet another embodiment of the present invention, a method for forming a vertically oriented interposer stack, the vertically oriented interposer stack defining a longitudinal direction, a lateral direction, and a vertical direction that are orthogonal to one another, includes forming a first external termination on a first side surface of each interposer of a plurality of interposers. The first side surface is opposite a second side surface along the vertical direction, and the first side surface and the second side surface each extend along the longitudinal direction from a first end surface to a second end surface that is opposite the first end surface along the longitudinal direction. The method further includes forming a second external termination on the first side surface of each interposer of a plurality of interposers and stacking the plurality of interposers along the lateral direction with a respective one component of a plurality of components disposed between each adjacent pair of interposers of the plurality of interposers. The plurality of interposers are stacked along the lateral direction such that the first external terminations of the plurality of interposers are generally aligned with one another along the lateral direction and the second external terminations of the plurality of interposers are generally aligned with one another along the lateral direction.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 illustrates a schematic side view of one embodiment of a vertical component stack assembly including a vertical component stack of the present invention;

FIG. 2 illustrates a bottom plan view of the vertical component stack of FIG. 1;

FIG. 3A illustrates a cross-sectional view of the vertical component stack of FIG. 1, taken along the line 3A-3A of FIG. 2;

FIG. 3B illustrates a cross-sectional view of the vertical component stack of FIG. 1, taken along the line 3B-3B of FIG. 2;

FIG. 4 a schematic side view of another embodiment of a vertical component stack assembly including a vertical component stack of the present invention;

FIG. 5A illustrates a schematic top view of one embodiment of a component may be employed in the present invention;

FIG. 5B illustrates a schematic side view of another embodiment of a component may be employed in the present invention;

FIG. 6 provides a flow chart of one embodiment of a method for forming a vertical component stack of the present invention;

FIG. 7 illustrates a schematic perspective view of one embodiment of a vertically oriented component stack assembly including a vertically oriented component stack of the present invention;

FIG. 8 illustrates a schematic side view of the vertically oriented component stack assembly of FIG. 7;

FIG. 9A illustrates a schematic side view of one embodiment of a component may be employed in the present invention;

FIG. 9B illustrates a schematic exploded view of another embodiment of a component may be employed in the present invention;

FIG. 10 illustrates a schematic perspective view of another embodiment of a vertically oriented component stack assembly including a vertically oriented component stack of the present invention;

FIG. 11A illustrates a schematic perspective view of a first end of a vertically oriented component stack that may be employed in the present invention;

FIG. 11B illustrates a schematic perspective view of a second end of the vertically oriented component stack of FIG. 11A;

FIG. 12 provides a flow chart of one embodiment of a method for forming a vertically oriented component stack of the present invention;

FIG. 13 illustrates a schematic perspective view of one embodiment of a vertically oriented interposer stack assembly including a vertically oriented interposer stack of the present invention;

FIG. 14 illustrates a schematic side view of the vertically oriented interposer stack assembly of FIG. 13; and

FIG. 15 provides a flow chart of one embodiment of a method for forming a vertically oriented component stack of the present invention.

Repeat reference to characters in the present specification and figures is intended to represent same or analogous features or elements of the invention.

### DETAILED DESCRIPTION OF THE INVENTION

It is to be understood by one of ordinary skill in the art that the present discussion is a description of exemplary embodiments only and is not intended as limiting the broader aspects of the present invention.

Generally speaking, the present invention is directed to vertical components, such as vertical component stacks, vertically oriented components, and vertically oriented interposer stacks. A vertical component stack can include a plurality of components that are stacked along a vertical direction such that at least a portion of each component in the stack is aligned in a longitudinal direction and a lateral direction. Each component of the plurality of components in the vertical component stack may include at least one electrode extending in a plane parallel to an X-Y plane defined by the longitudinal direction and the lateral direction. The at least one electrode of each component can be parallel to a mounting surface of a device on which the vertical component stack is mounted.

A vertically oriented component stack can include a plurality of components that are stacked in a lateral direction such that at least a portion of each component is aligned in a vertical direction and a longitudinal direction. Each component in the vertically oriented component stack can have external terminations along only one side, i.e., along the same side. Such side terminations can allow the vertically oriented component stack to be mounted, e.g., to a device such as a printed circuit board, with the components oriented vertically and perpendicular to the mounting surface.

A vertically oriented interposer stack may be similar to the vertically oriented component stack and include interposers that are each terminated along the same side as the other interposers of the stack. A conductive pattern may be deposited or formed on a surface of one or more interposers, and a component, such as a filter, may be disposed in electrical contact with the conductive pattern. The component may be sandwiched between two interposers in the stack. The stack may include a plurality of interposers with components sandwiched between the interposers to form a component bank.

Each of the vertical components described herein may be customizable. For instance, each component stack or bank may be custom designed to include a number of components that are needed for a particular application, e.g., to perform filtering functions at a given frequency or over a given frequency range. Thus, each component stack or bank may be tailored as needed to achieve desired performance of the stack or bank.

In some embodiments, the vertical component (whether the vertical component stack, vertically oriented component stack, or vertically oriented interposer stack) includes at least one filter. The filter can be a thin-film filter, a multilayer filter, or any other suitable filter. In some embodiments, the vertical component can include more than one filter, and each filter in the vertical component may be of the same type (e.g., all thin-film filters or all multilayer filters) or at least one filter of the multiple filters may be of a different type.

As stated above, the vertical component may include at least one thin-film filter. The thin-film filter can include a monolithic substrate and at least one thin-film inductor formed over the monolithic substrate. For example, the thin-film filter may include a patterned conductive layer forming one or more thin-film inductors. In some embodiments, the thin-film inductors can be relatively thick for thin-film components, each thin-film inductor having a thickness that ranges from 20 micrometers to about 80 micrometers, in some embodiments from about 30 micrometers to about 70 micrometers, in some embodiments from about 40 micrometers to about 60 micrometers, and in some embodiments from about 45 micrometers to about 55 micrometers. Such thicknesses have been found to reduce heat generation by the thin-film inductors when large power currents are applied, but such thicknesses are not so large as to prevent strong adhesion between substrate and/or dielectric layers that are adjacent the thin-film inductors. In other embodiments, the one or more thin-film inductors may be thinner, i.e., have a thickness less than 20 micrometers.

The one or more thin-film filters may be precisely formed using a variety of suitable subtractive, semi-additive, or fully additive processes. For example, physical vapor deposition and/or chemical deposition may be used. For instance, in some embodiments, thin film components may be formed using sputtering, a type of physical vapor deposition. A variety of other suitable processes may be used, however, including evaporation, atomic layer deposition (ALD), plasma-enhanced chemical vapor deposition (PECVD), electroless plating, and electroplating, for example. Lithography masks and etching may be used to produce the desired shape of the thin film components. A variety of suitable etching techniques may be used including dry etching using a plasma of a reactive or non-reactive gas (e.g., argon, nitrogen, oxygen, chlorine, boron trichloride, carbon tetrafluoride, sulfur hexafluoride) and/or wet etching.

As described above, in some embodiments, the vertical component includes at least one multilayer filter. The multilayer filter may include an inductor including a conductive layer formed over a first dielectric layer. The multilayer filter may further include a capacitor including a first electrode and a second electrode that is separated from the first electrode by a second dielectric layer. In some embodiments, the second dielectric layer may be distinct from the first dielectric layer, i.e., the capacitor may be separated from the inductor by in a vertical, Z-direction (e.g., by one or more dielectric layers), for example by at least 10 microns, in some embodiments at least about 20 microns, in some embodiments at least about 30 microns, in some embodiments at least about 40 microns, in some embodiments at least about 50 microns, in some embodiments at least about 60 microns, in some embodiments at least about 80 microns, and in some embodiments at least about 150 microns. Such separation between the inductor and conductor electrodes can reduce interference and produce excellent performance characteristics at high frequencies.

The at least one filter of the vertical component may include one or more dielectric materials, e.g., as a filter substrate, as one or more dielectric layers, etc. In some embodiments, the one or more dielectric materials may have a low dielectric constant. The dielectric constant may be less than about 120, in some embodiments less than about 100, in some embodiments less than about 75, in some embodiments less than about 50, in some embodiments less than about 25, in some embodiments less than about 15, and in some embodiments less than about 5. For instance, in some embodiments, the dielectric constant may range from about 1.5 to about 120, in some embodiments from about 1.5 to about 100, in some embodiments from about 1.5 to about 75, and in some embodiments from about 2 to about 8. For example, a dielectric material having a dielectric constant higher than 30 may be used to achieve higher frequencies and/or smaller components. In such embodiments, the dielectric constant may range from about 30 to about 120, or greater, in some embodiments from about 50 to about 100, and in some embodiments from about 70 to about 90.

In some embodiments, the one or more dielectric materials may include organic dielectric materials. Example organic dielectric include polyphenyl ether (PPE) based materials, such as LD621 from Polyclad and N6000 series from Park/Nelco Corporation, liquid crystalline polymer (LCP), such as LCP from Rogers Corporation or W. L. Gore & Associates, Inc., hydrocarbon composites, such as 4000 series from Rogers Corporation., and epoxy-based laminates, such as N4000 series from Park/Nelco Corp. For instance, examples include epoxy based N4000-13, bromine-free material laminated to LCP, organic layers with high K material, unfilled high-K organic layers, Rogers 4350, Rogers 4003 material, and other theremoplastic materials such as polyphenylene sulfide resins, polyethylene terephthalate resins, polybutylene terephthalate resins, polyethylene sulfide resins, polyether ketone resins, polytetraflouroethylene resins and graft resins, or similar low dielectric constant, low-loss organic material.

In some embodiments, the dielectric material may be a ceramic-filled epoxy. For example, the dielectric material may include an organic compound, such as a polymer (e.g., an epoxy) and may contain particles of a ceramic dielectric material, such as barium titanate, calcium titanate, zinc oxide, alumina with low-fire glass, or other suitable ceramic or glass-bonded materials. In some embodiments, the dielectric material may be an organic compound such as an epoxy (with or without ceramic mixed in, with or without fiberglass), popular as circuit board materials, or other plastics common as dielectrics. In these cases, the conductor is usually a copper foil which is chemically etched to provide the patterns. In still further embodiments, dielectric material may comprise a material having a relatively high dielectric constant (K), such as one of NPO (COG), X7R, X5R X7S, Z5U, Y5V and strontium titanate. In such examples, the dielectric material may have a dielectric constant that is greater than 100, for example within a range from between about 100 to about 4000, in some embodiments from about 1000 to about 3000.

Other materials may be utilized, however, including, N6000, epoxy based N4000-13, bromine-free material laminated to LCP, organic layers with high K material, unfilled high-K organic layers, Rogers 4350, Rogers 4003 material (from the Rogers Corporation), and other theremoplastic materials such as hydrocarbon, Teflon, FR4, epoxy, polyamide, polyimide, and acrylate, polyphenylene sulfide resins, polyethylene terephthalate resins, polybutylene terephthalate resins, polyethylene sulfide resins, polyether ketone resins, polytetraflouroethylene resins, BT resin composites (e.g., Speedboard C), thermosets (e.g., Hitachi MCL-LX-67F), and graft resins, or similar low dielectric constant, low-loss organic material.

Additionally, in some embodiments, non-organic dielectric materials may be used including a ceramic, semi-conductive, or insulating materials, such as, but not limited to, sapphire, ruby, alumina (Al₂O₃), aluminum nitride (AlN), beryllium oxide (BeO), aluminum oxide (Al₂O₃), boron nitride (BN), silicon (Si), silicon carbide (SiC), silica (SiO₂), silicon nitride (SisN₄), gallium arsenide (GaAs), gallium nitride (GaN), zirconium dioxide (ZrO₂), mixtures thereof, oxides and/or nitrides of such materials, or any other suitable ceramic material. Additional example ceramic materials include barium titanate (BaTiO₃), calcium titanate (CaTiO₃), zinc oxide (ZnO), ceramics containing low-fire glass, or other glass-bonded materials. Dielectric materials such as diamond may be used as well.

Suitable dielectric materials are generally electrically insulating and thermally conductive. For example, in some embodiments, the filter may include a filter substrate having a relatively high thermal conductivity, which may improve the device's power handling capabilities. For instance, the substrate can have a thermal conductivity that is greater than about 20 W/m.° C., in some embodiments greater than about 40 W/m.° C., in some embodiments greater than about 80 W/m.° C., and in some embodiments greater than about 100 W/m·° C.

Each of the one or more filters of the vertical component may be configured as a variety of suitable filter types, including, for example, a low pass filter, a high pass filter, or a bandpass filter. Each filter may have a characteristic frequency (e.g., a low pass frequency, high pass frequency, an upper bound of a band pass frequency, or a lower bound of a band pass frequency (e.g., a stop band frequency)) that ranges from about 100 MHz to about 5 GHZ, or higher, in some embodiments from about 150 MHz to about 4 GHZ, in some embodiments from about 200 MHz to about 3 GHZ.

Further, each filter of the vertical component may have a number of conductive layers and non-conductive layer forming structures (e.g., inductors, connectors, terminals, etc.) and connections therebetween as described herein. In some embodiments, the filter may have two or more conductive layers, in some embodiments four or more conductive layers, and in some embodiments six or more conductive layers.

In some embodiments, each filter of the vertical component may include a signal path having an input and an output. An inductor of each filter may form a portion of the signal path or may be connected between the signal path and ground. The signal path may include one or more conductive layers formed over one or more of the dielectric layers. As used herein, a conductive layer “formed over” a dielectric layer may refer to a conductive layer formed directly on the dielectric layer. However, one or more thin intermediate layers or coatings may be located between the conductive layer and/or dielectric layer.

The conductive layers may include a variety of conductive materials. For example, the conductive layers may include copper, nickel, gold, silver, or other metals or alloys.

The conductive layers may be formed using a variety of suitable techniques. Subtractive, semi-additive or fully additive processes may be employed with panel or pattern electroplating of the conductive material followed by print and etch steps to define the patterned conductive layers. Photolithography, plating (e.g., electrolytic), sputtering, vacuum deposition, printing, or other techniques may be used to for form the conductive layers. For example, a thin layer (e.g., a foil) of a conductive material may be adhered (e.g., laminated) to a surface of a dielectric layer. The thin layer of conductive material may be selectively etched using a mask and photolithography to produce a desired pattern of the conductive material on the surface of the dielectric material.

Regardless of filter type (e.g., thin-film, multilayer, or other type), the vertical component may include a filter having at least one inductor. The inductor may include a conductive layer formed over a dielectric layer, e.g., a patterned conductive layer formed over a dielectric layer. The inductor may form a loop or a partial loop, e.g., the inductor may extend a full 360° about a central point or may extend over only a portion of a 360° path about the central point, such as about 340°, about 315°, about 300°, about 180°, about 135°, about 90°, or less. The loop may have a single loop diameter that ranges from about 2 mm to about 9 mm, in some embodiments from about 3 mm to about 7 mm. In some embodiments, the conductive layer shaped in a loop or a partial loop is formed entirely on a single layer. For example, multiple inductors may be formed entirely in the same conductive layer and/or plane. However, in other embodiments, whether formed as a loop, a partial loop, or other shape (such as one or more straight lines), the inductor(s) can respectively include at least two conductive layers spaced apart from each other in a thickness direction of the filter and connected by one or more vias. The conductive layers may be spaced apart by one or more dielectric layers, including one or more suitable dielectric materials, including those described above. In some embodiments, at least some of the dielectric layers may have thicknesses that are less than about 180 microns, in some embodiments less than about 100 microns, in some embodiments less than about 40 microns, and in some embodiments less than about 20 microns.

The inductor(s) may have a line width a width that is greater than about 0.1 mm, in some embodiments greater than about 0.2 mm, in some embodiments greater than about 0.3 mm, and in some embodiments greater than about 0.5 mm, and in some embodiments greater than about 1 mm.

In some embodiments, one or more inductors of the component may include at least one corner. The corner may have an angle greater than about 15 degrees, in some embodiments greater than about 30 degrees, in some embodiments greater than about 45 degrees, and in some embodiments greater than about 60 degrees (e.g., about 90 degrees). An inductor may have from one to nine corners, or more, in some embodiments, the inductor may have fewer than six corners, in some embodiments fewer than four corners, in some embodiments fewer than three corners, and in some embodiments fewer than two corners. In some embodiments, one or more inductors may be free of any corners. As described above, in some embodiments, one or more inductors may define a full loop or less, e.g., an inductor of the component may define less than one half of a loop.

Although the vertical component is described above as having one or more filters stacked together to form the vertical component, it will be appreciated that the vertical component stack, vertically oriented component stack, or vertically oriented interposer stack may include other components as well. For instance, the stack could include one or more capacitors (such as one or more multilayer ceramic capacitors (MLCCs) or the like), varistors, resistors, inductors, fuses, diodes, transformers, sensors, electrostatic discharge (ESD) devices, memory devices, radio frequency devices, power amplifiers, power management devices, antennas, and/or microelectromechanical systems (MEMS) devices. Such components could be used individually to form a respective one component of the plurality of components stacked together in the vertical or vertically oriented stack of components, or one or more components could be disposed on a substrate and electrically connected to one another (or otherwise combined together) to form a respective one component of the plurality of components stacked together in the vertical or vertically oriented stack of components.

In some embodiments, each component of the plurality of components in the vertical component stack, vertically oriented component stack, or vertically oriented interposer stack may generally be compact. For example, each component may have a length that is less than about 150 mm, in some embodiments less than about 100 mm, in some embodiments less than about 80 mm, in some embodiments less than about 50 mm, in some embodiments less than about 30 mm, in some embodiments less than about 15 mm, in some embodiments less than about 8 mm, and in some embodiments less than about 1 mm. Further, each component may have a width that is less than about 100 mm, in some embodiments less than about 60 mm, in some embodiments less than about 40 mm, in some embodiments less than about 20 mm, in some embodiments less than about 15 mm, in some embodiments less than about 10 mm, in some embodiments less than about 5 mm, and in some embodiments less than about 1 mm.

Moreover, each component of the plurality of components in the vertical component stack, vertically oriented component stack, or vertically oriented interposer stack may generally be low-profile or thin. For instance, in some embodiments, each component may have an overall thickness that ranges from about 100 microns to about 2 mm, in some embodiments from about 150 microns to about 1 mm, and in some embodiments from about 200 microns to about 300 microns.

In some embodiments, may include at least one interposer. The interposer generally includes an insulating material. In one embodiment, for instance, the insulating material may be an organic material, such as bismaleimide triazine (BT) resin materials (e.g., BT, BT-epoxy resins, etc.), epoxy resin materials (e.g., glass fiber-reinforced epoxy resin (e.g., FR4)), polyimide materials, and/or low-k and ultra-low-k dielectrics (e.g., carbon-doped dielectric, fluorine-doped dielectric, porous dielectric, and an organic polymeric dielectric). The insulating material may also be an inorganic interposer, such as those formed from ceramic materials (e.g., glass), as well as from semiconductor materials, such as silicon, germanium, aluminum nitride (AlN), and other group III-V (e.g., gallium nitride) and group IV materials.

In some embodiments, the interposer may include one or more conductive pathways through the insulating material (e.g., including conductive traces and/or conductive vias). The conductive pathways may serve as a mechanism for electrically connecting the interposer to an adjacent structure or for routing electrical signals through the interposer. Such pathways may include one or more metal interconnects and vias as is known in the art. In one embodiment, for example, the interposer may be formed from silicon and the vias may be formed therein may that are referred to as “through-silicon vias” (TSVs).

As used herein, “formed over,” may refer to a layer that is directly in contact with another layer. However, intermediate layers may also be formed therebetween. Additionally, when used in reference to a bottom surface, “formed over” may be used relative to an exterior surface of the component. Thus, a layer that is “formed over” a bottom surface may be closer to the exterior of the component than the layer over which it is formed.

Various embodiments of the present invention will now be described in more detail below.

### I. Vertical Component Stack and Assembly

Generally, a vertical component stack includes a plurality of components that are stacked along a vertical direction such that at least a portion of each component in the stack is aligned in a longitudinal direction and a lateral direction. For example, the vertical component stack may define a longitudinal direction, a lateral direction, and a vertical direction that are orthogonal to one another, and a plurality of components of the vertical component stack may include an upper surface and a lower surface opposite the upper surface along the vertical direction. The upper surface may extend in a first plane parallel to an X-Y plane defined by the longitudinal direction and the lateral direction, and the lower surface may extend in a second plane parallel to the X-Y plane, such that the first plane and the second plane are parallel to one another. The plurality of components may be stacked along the vertical direction such that a lower surface of a second component of the plurality of components is disposed over an upper surface of a first component of the plurality of components. One or more ports, such as an input and an output of each component of the plurality of components, may be exposed on a lower surface of the first component of the plurality of components. The vertical component stack may be disposed on a mounting surface of a device, such as a printed circuit board (PCB) or the like, with the input and output of each component electrically connected to the device, to form a vertical component stack assembly.

The present inventors have discovered that such a vertical component stack frees up space on the device. For example, rather than attaching individual components to a mounting surface of a PCB, the components can be stacked such that the footprint on the PCB for the components is reduced to the footprint of one component rather than the sum of the footprints of each component. Further, by routing the connection between each component and the board to a single component surface (e.g., the component surface of the vertical component stack that interfaces with the device), the space occupied by the vertical component stack is further reduced compared to traditional component/device assemblies. For instance, rather than electrical connections with a PCB that may extend beyond a footprint of a component, all of the electrical connections for the plurality of components in the vertical component stack are made within the footprint of a single component. Moreover, stacked components may be connected to a board, etc. using shorter pathways than traditional layouts, which can prevent losses and improve overall performance at high frequencies.

In some embodiments, the one or more ports may include at least one ground for each component of the plurality of components. As such, in some embodiments, a plurality of inputs, outputs, and grounds may be exposed on the lower surface of the first component, which may be disposed on a mounting surface of a device as described herein. The plurality of inputs, outputs, and grounds on the lower surface of the first component may be in electrical contact with the device to electrically connect the plurality of components with the device.

A via may extend between a respective one port exposed on the lower surface of the first component to a respective one component, e.g., to electrically connect the respective one port with the respective one component. For example, in some embodiments, an input via extends from an input port exposed on the lower surface of the first component of the plurality of components to a respective one component of the plurality of components, and an output via extends from an output port exposed on the lower surface of the first component of the plurality of components to the respective one component of the plurality of components. In embodiments having grounds exposed on the lower surface of the first component of the vertical component stack, a ground via may extend from the at least one ground port exposed on the lower surface of the first component to a respective one component of the plurality of components. As such, a via may electrically connect each component of the plurality of components with a respective one input, a respective one output, and/or a respective one ground exposed on the lower surface of the first component. Each input via, each output via, and each ground via may pass through the first component of the plurality of components to the lower surface of the first component of the plurality of components. Some of the input vias, output vias, and ground vias may also pass through other components of the plurality of components to connect a component higher in the vertical component stack with the respective input, output, or ground on the lower surface of the first component in the vertical component stack.

Thus, in some embodiments, one or more vias may be formed in the plurality of components. In some embodiments, the via(s) may electrically connect different conductive layers of a component of the plurality of components, such as different conductive layers of a filter. For example, a via may be formed in the dielectric layer on which the conductive layer of an inductor is formed. Such via may connect the inductor with another part of the filter, such as a portion of a signal path or a ground. In some embodiments, the length of such via in a Z-direction may be equal to the thickness of the dielectric layer in which such via is formed. For example, such via may have a length that is less than about 180 microns, in some embodiments less than about 100 microns, and in some embodiments less than about 80 microns.

In other embodiments, a via may be formed in the vertical component stack to connect a respective component with one or more ports exposed on the lower surface of the first component, such as an input, an output, or a ground exposed on the lower surface of the first component. For example, such via may connect the signal path of a filter with an input, an output, or a ground exposed on the lower surface of the first component. In some embodiments, the length of such via may be within a range of about 5% to 100% of a thickness of the vertical component stack, with the thickness defined in the vertical or stack direction. That is, the via may extend through some or all of the vertical component stack, and as such, one or more components stacked along the vertical direction to form the vertical component stack, to connect a respective one component with a port exposed on the lower surface of the first component of the stack.

The via(s) may have a variety of suitable widths. For instance, in some embodiments the width of the via may range from about 20 microns to about 200 microns, in some embodiments from about 40 microns to about 180 microns, in some embodiments from about 60 microns to about 140 microns, and in some embodiments from about 80 microns to about 120 microns.

The via(s) may include a variety of conductive materials, such as copper, nickel, gold, silver, or other metals or alloys. The vias may be formed by drilling (e.g., mechanical drilling, laser drilling, etc.) through holes and plating the through holes with a conductive material, for example using electroless plating or seeded copper. The via(s) may be filled with conductive material such that a solid column of conductive material is formed. Alternatively, the interior surfaces of the through holes may be plated such that the via(s) are hollow.

The vertical component stack may include any suitable number of components stacked along the vertical direction. For example, in some embodiments, the vertical component stack includes at least three components stacked along the vertical direction. As described above, the first component of the at least three components may be the bottommost component along the vertical direction, with the lower surface of the second component disposed over the upper surface of the first component. A lower surface of a third component of the at least three components may be disposed over an upper surface of the second component such that the second component is disposed between the first component and the third component in the vertical direction. That is, the second component may be sandwiched between the first component and the third component. In embodiments including only three components, the third component is the topmost component in the vertical component stack, but in embodiments including more than three components, the third component may be sandwiched between other components like the second component. For instance, the vertical component stack may include four, five, six, seven, or more components stacked along the vertical direction such that the third component is sandwiched in the stack.

In some embodiments, the vertical component stack includes at least one filter. For example, at least one component of the plurality of components in the stack may be a filter. The at least one filter may be any suitable filter type, such as a thin-film filter or a multilayer filter, such as described above, or any other suitable filter. The filter may include a signal path having an input and an output. The filter may be configured to filter signals from the input and produce a filtered output signal at the output. In some embodiments, a plurality of dielectric layers may have conductive layers formed thereon that are selectively shaped or patterned to form capacitors and/or inductors that, when stacked together, form the filter.

In some embodiments, an interposer is disposed between at least one adjacent pair of components of the plurality of components. For instance, an interposer may be disposed between the first component of the plurality of components and the second component of the plurality of components. In some embodiments, the vertical component stack includes a plurality of interposers, with a respective one interposer of the plurality of interposers is disposed between each adjacent pair of components of the plurality of components. An interposer between an adjacent pair of components may electrically isolate the components of the adjacent pair of components from one another, which may improve the performance of the vertical component stack. It will be appreciated that the one or more vias connecting components in the stack to respective ports exposed on the lower surface of the first component may pass through an interposer as needed to reach the lower surface of the first component. Further, as described above, each interposer may be formed from a suitable material, and in some embodiments, the interposer includes a substrate comprising aluminum, such as aluminum nitride (AlN).

The vertical component stack may be configured for mounting on a mounting surface of a device to form an assembly, e.g., a vertical component stack assembly. The assembly may include a device having a mounting surface, such as a printed circuit board or the like, and a vertical component stack such as described herein. The mounting surface of the device may extend in a mounting plane parallel to the X-Y plane, and the vertical component stack may be disposed on the mounting surface such that the first plane and the second plane of each component of the plurality of components is parallel to the mounting plane. As one example, where at least one component of the plurality of components of the stack is a filter including an inductor having a conductive layer and a capacitor having a first electrode and a second electrode, the vertical component stack may be disposed on the mounting surface such that the conductive layer, the first electrode, and the second electrode each extend in the longitudinal direction and the lateral direction (e.g., in one or more planes parallel to the X-Y plane) parallel to the mounting surface.

As described herein, one or more ports (such as an input, an output, and a ground for each component in the component stack) may be exposed on the lower surface of the first component of the plurality of components in the vertical component stack. Each port exposed on the lower surface of the first component may be in contact with a contact area on the mounting surface of the device, e.g., to electrically connect the vertical component stack with the device.

In some embodiments, the contact area is a plurality of separate contact areas, and the plurality of separate contact areas includes a separate contact area corresponding to a respective one port. For example, the plurality of separate contact areas may include a separate contact area corresponding to a respective one input, output, and ground exposed on the lower surface of the first component of the plurality of components.

The assembly may also include one or more switches, e.g., embedded in or otherwise attached to or mounted on the device and electrically connected to the plurality of components of the vertical component stack. For instance, a switch of the device may be electrically connected to a respective one component of the plurality of components of the vertical component stack. The one or more switches can allow selective enablement of components of the vertical component stack. For example, the one or more switches may allow one or more components of the vertical component stack to be selectively activated and deactivated, e.g., based on an operating frequency range, a desired performance characteristic, a power or other load, thermal or heat management, and/or other operational needs or goals.

The present disclosure also provides methods for forming a vertical component stack such as described herein. The present disclosure may also provide methods for forming an assembly having a device and a vertical component stack disposed thereon, as well be appreciated by those having ordinary skill in the art based on the present disclosure.

A method for forming a vertical component stack can include stacking a plurality of components along a vertical direction, e.g., such that a lower surface of a second component of the plurality of components is disposed over an upper surface of a first component of the plurality of components. As described elsewhere herein, the upper surface and the lower surface of each component may lie in a plane that is parallel to an X-Y plane defined by the longitudinal direction and the lateral direction, which are perpendicular to one another and are both perpendicular to the vertical direction.

The method for forming the vertical component stack can further include defining a plurality of vias, each via extending between a respective one component of the plurality of components and a lower surface of the first component of the plurality of components. The method can also include exposing a plurality of ports along the lower surface of the first component, and each via can extend between a respective one component of the plurality of components and a respective one port of the plurality of ports, e.g., to electrically connect a respective component with a port exposed on the lower surface of the first component. Thus, as described above, each of the plurality of vias can extend through the first component to electrically connect a respective component with at least one port exposed along the lower surface of the first component.

In some embodiments, the plurality of ports include inputs, outputs, and grounds. For example, exposing the plurality of ports on the lower surface of the first component may include exposing an input and an output of each component of the plurality of components on a lower surface of the first component and, in at least some embodiments, exposing a plurality of grounds on the lower surface of the first component of the plurality of components, the plurality of grounds including at least one ground for each component of the plurality of components. In such embodiments, defining the plurality of vias can include defining a plurality of input vias, a respective one input via extending from the input exposed on the lower surface of the first component of the plurality of components to a respective one component of the plurality of components; defining a plurality of output vias, a respective one output via extending from the output exposed on the lower surface of the first component of the plurality of components to the respective one component of the plurality of components; and defining a plurality of ground vias, a respective one ground via extending from a respective one ground of the plurality of grounds exposed on the lower surface of the first component of the plurality of components to a respective one component of the plurality of components.

In some embodiments, the method can also include disposing an interposer between adjacent components such that at least two adjacent components are separated from one another by the interposer. As described above, in some embodiments, the method may include disposing an interposer between each adjacent pair of components of the plurality of components, such that each component is separated from an adjacent component by an interposer. In embodiments including at least one interposer, defining the plurality of vias includes defining vias through each interposer vertically below the component that the via is connecting to a port on the lower surface of the first component. For example, an interposer may be disposed between the second component and the first component such that the vertical component stack includes the first component as the bottommost component, the interposer stacked on top of the first component along the vertical direction, and the second component stacked on top of the interposer along the vertical direction. In such an embodiment, a via connecting the second component to a port on the lower surface of the first component is defined in the second component, the interposer, and the first component, e.g., the via is defined from the port on the lower surface of the first component to the second component, passing through the interposer that is disposed between the first component and the second component.

### Example Embodiments

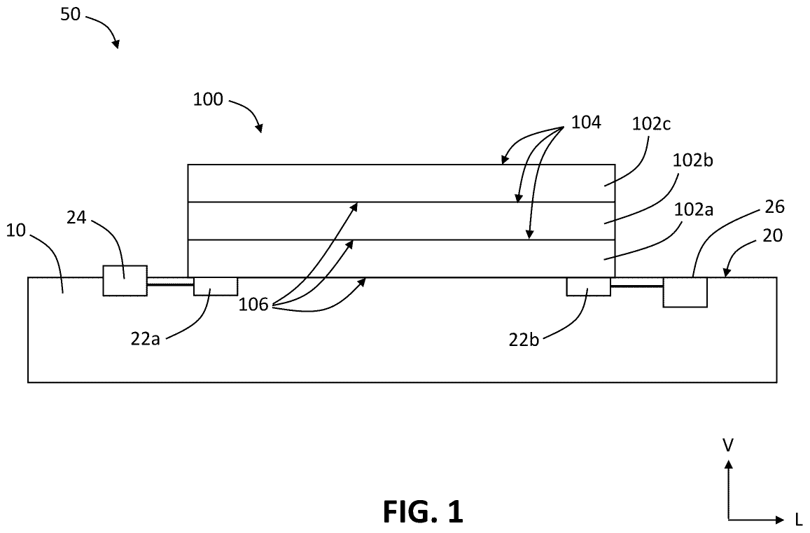

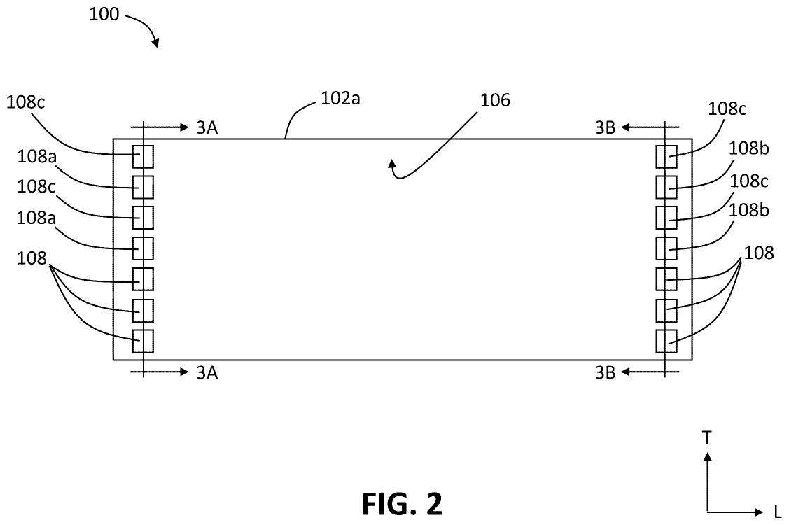

Referring now to the figures, FIG. 1 provides a schematic side view of a vertical component stack 100 disposed on a mounting surface 20 of a device 10. FIG. 2 provides a bottom view of the vertical component stack 100. The illustrated vertical component stack 100 has three components 102 stacked along a vertical direction V. The three components 102 include a first component 102a, a second component 102b, and a third component 102c. It will be appreciated that, in other embodiments, additional components 102 could be stacked together along with the vertical direction V with the three components 102 illustrated in FIG. 1. The vertical component stack 100 may be disposed on the mounting surface 20 of the device 10, which may be a printed circuit board (PCB) or the like, such that one or more of the components 102 are electrically connected to the device 10 as described herein. Together, the vertical component stack 100 and the device 10 form a vertical component stack assembly 50. Further, the vertical component stack 100 also may be referred to as a component bank having components vertically stacked together.

Keeping with FIG. 1, each of the components 102 of the vertical component stack 100 includes an upper surface 104 and a lower surface 106 opposite the upper surface 104 along the vertical direction V. The upper surface 104 of each component 102 may extend in a first plane parallel to an X-Y plane defined by a longitudinal direction L and a lateral direction T (FIG. 2). The lower surface 106 of each component 102 may extend in a second plane parallel to the X-Y plane, e.g., as shown in FIG. 2. As such, the first plane and the second plane are parallel to one another.

As shown in FIG. 1, the plurality of components 102 are stacked along the vertical direction V such that the lower surface 106 of the second component 102b is disposed over the upper surface 104 of the first component 102a. Referring to FIG. 2, one or more ports 108, such as an input 108a and an output 108b of one or more of the components 102 in the stack 100, may be exposed on the lower surface 106 of the first component 102a. In some embodiments, the one or more ports 108 may include at least one ground 108c for each component 102. As such, in some embodiments, a plurality of inputs 108a, outputs 108b, and grounds 108c may be exposed on the lower surface 106 of the first component 102a, which may be disposed on the mounting surface 20 of the device 10 as shown in FIG. 1. The plurality of inputs 108a, outputs 108b, and grounds 108c, and/or other types of ports 108, on the lower surface 106 of the first component 102a may be in electrical contact with the device 10 to electrically connect the plurality of components 102 with the device 10. It will be appreciated that, although only a portion of the ports 108 shown in FIG. 2 are labeled as inputs 108a, outputs 108b, and grounds 108c, in some embodiments, each of the ports 108 exposed on the lower surface 106 of the first component 102a may be one of an input 108a, output 108b, or ground 108c. However, in other embodiments, none or only a portion of the ports 108 exposed on the lower surface 106 of the first component 102a may be inputs 108a, outputs 108b, and grounds 108c.

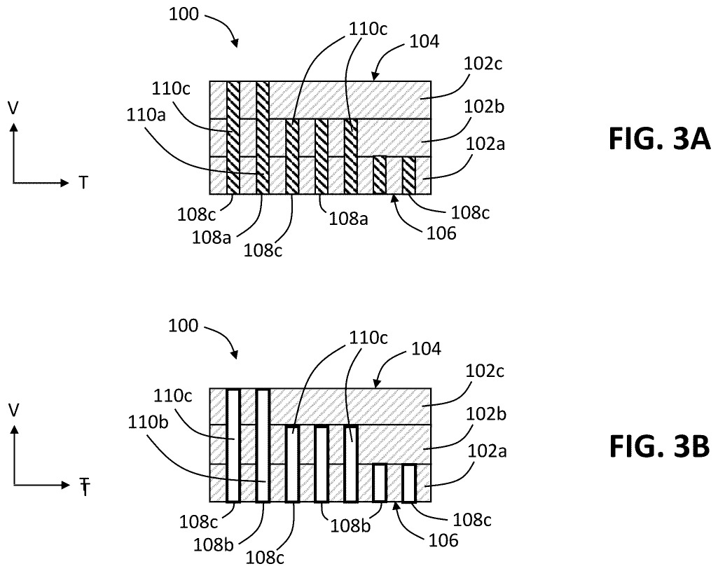

Turning to FIGS. 3A and 3B, cross-sectional views are provided of the vertical component stack 100, taken along the lines 3A-3A and 3B-3B of FIG. 2. As shown in FIGS. 3A and 3B, a via 110 may extend between a respective one port 108 exposed on the lower surface 106 of the first component 102a to a respective one component 102, e.g., to electrically connect the respective one port 108 with the respective one component 102. For instance, in some embodiments, an input via 110a extends from the input 108a exposed on the lower surface 106 of the first component 102a to the third component 102c, e.g., to a conductive layer of the third component 102c. Similarly, in some embodiments, an output via 110b (not shown) extends from the output 108b exposed on the lower surface 106 of the first component 102a to the third component 102c, e.g., to the conductive layer of the third component 102c. Further, in the illustrated embodiment, a ground via 110c extends from the at least one ground 108c exposed on the lower surface 106 of the first component 102a to the third component 102c, e.g., to the conductive layer of the third component 102c. Input vias 110a, output vias 110b, and ground vias 110c may also extend from the respective input ports 108a, output ports 108b, and ground ports 108c exposed on the lower surface 106 of the first component 102a to another respective component 102 of the vertical component stack 100, e.g., to a conductive layer of the second component 102b and to a conductive layer of the first component 102a. As such, a via 110 may electrically connect each component 102 with a respective one port 108, such as a respective one input 108a, a respective one output 108b, and/or a respective one ground 108c exposed on the lower surface 106 of the first component 102a.

As illustrated in FIGS. 3A and 3B, each via 110 passes through the first component 102a to the lower surface 106 of the first component 102a. Some of the vias 110 also pass through other components 102 of the stack 100, e.g., some vias 110 pass through the second component 102b and some pass through the second component 102b and the third component 102c, to connect a component 102 higher in the vertical component stack 100 than the first component 102a with the respective port 108 on the lower surface 106 of the first component 102a.

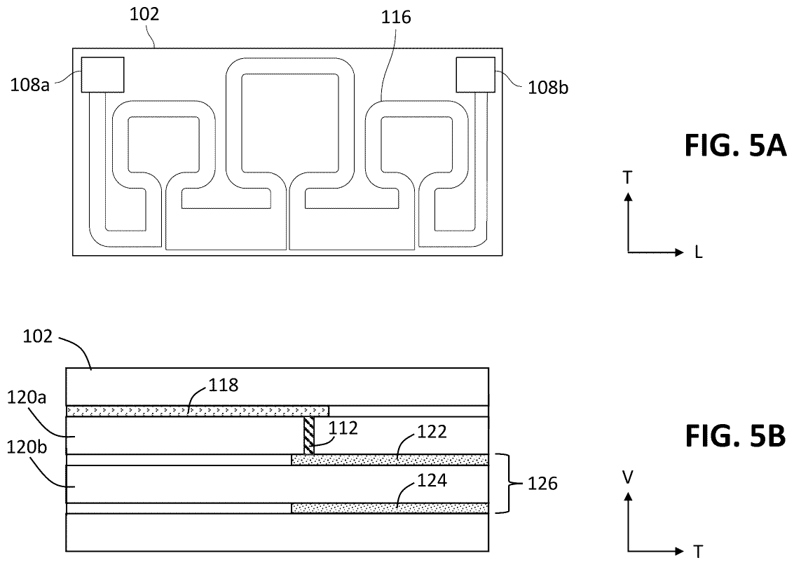

One or more vias 112 also may be defined in the vertical component stack 100, e.g., to interconnect two or more components 102 of the stack 100 and/or to electrically connect elements of a component 102. For instance, referring to FIG. 5B, a via 112 may electrically connect an inductor 118 formed over a first dielectric layer 120a of a component 102 with a first electrode 122 formed over a second dielectric layer 120b of the component 102. Other vias 112 may extend between components 102, without connecting to a port 108 like vias 110, e.g., to electrically connect two or more components 102 within the vertical component stack 100.

Referring back to FIGS. 3A and 3B, it will be appreciated that the vias 110, 112 may be through holes filled with conductive material such that a solid column of conductive material is formed, as shown in FIG. 3A, or the vias may be through holes having the interior surfaces thereof plated with conductive material such that the vias 110, 112 are hollow, as shown in FIG. 3B. Exemplary conductive materials and methods for forming the via through holes are described elsewhere herein.

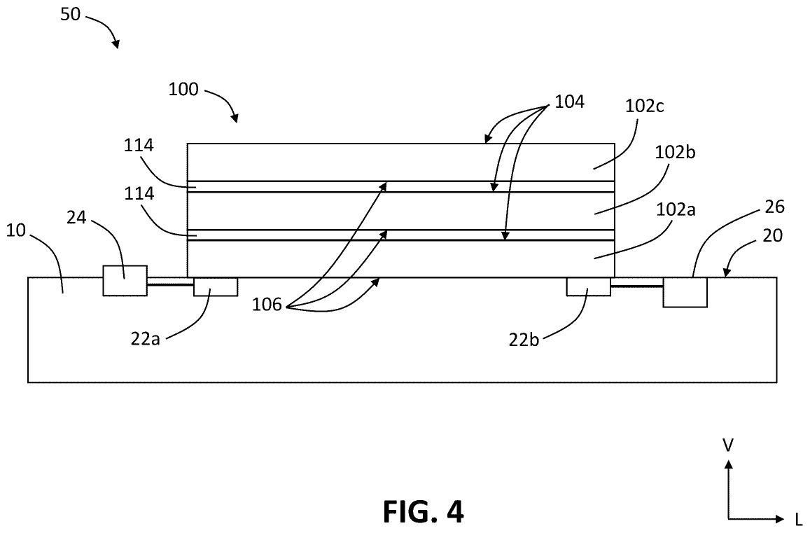

Turning to FIG. 4, a schematic side view is provided of another embodiment of the vertical component stack 100 and assembly 50. In the embodiment depicted in FIG. 4, an interposer 114 is disposed between each adjacent pair of components 102. More particularly, an interposer 114 is disposed between the first component 102a and the second component 102b, and another interposer 114 is disposed between the second component 102b and the third component 102c. Although not illustrated in FIG. 4, it will be appreciated that the one or more vias 110 connecting components 102 in the stack 100 to respective ports 108 exposed on the lower surface 106 of the first component 102a may pass through an interposer 114 as needed to reach the lower surface 106 of the first component 102a.

Referring now to FIGS. 5A and 5B, in some embodiments, at least one component 102 in the vertical component stack 100 is a filter. The at least one filter may be any suitable filter type, such as a thin-film filter as shown in FIG. 5A, a multilayer filter as shown in FIG. 5B, or any other suitable filter. For example, referring to FIG. 5A, at least one component 102 may be a thin-film filter having an inductor including a patterned conductive line 116 extending between an input 108a and an output 108b, which may be connected to the patterned conductive line 116 with an input via 110a and an output via 110b, respectively, as described, e.g., with respect to FIGS. 3A and 3B. As described elsewhere herein, the patterned conductive line 116 may include at least one full loop (such as three loops as shown in FIG. 5A) or one or more partial loops, although straight line segments also may be used to define one or more inductors. Referring to FIG. 5B, at least one component 102 may be a multilayer filter having a conductive layer formed over a first dielectric layer 120a to define an inductor 118, and a first electrode 122 formed over a second dielectric layer 120b and a second electrode 124 formed over a third dielectric layer 120c to define a capacitor 126. It will be appreciated that the filter elements shown in FIGS. 5A and 5B are by way of example only, and each filter component 102 included in the vertical component stack 100 may be configured as needed based on, e.g., filter type (e.g., low-pass, high-pass, or passband), characteristic frequency (e.g., 6 GHZ, 8 GHZ, 12 GHZ, or a higher or a lower characteristic frequency), etc.

Referring to FIGS. 1 and 4, the mounting surface 20 of the device 10 of the vertical component stack assembly 50 may extend in a mounting plane parallel to the X-Y plane, and the vertical component stack 100 may be disposed on the mounting surface such that the first plane (defined by the component upper surfaces 104) and the second plane (defined by the component lower surfaces 106) of each component 102 is parallel to the mounting plane. As one example, where at least one component 102 of the vertical component stack 100 is a filter including an inductor 118 having a conductive layer and a capacitor 126 having a first electrode 122 and a second electrode 124, the vertical component stack 100 may be disposed on the mounting surface 20 such that the conductive layer of the inductor 118, the first electrode 122, and the second electrode 124 each extend in the longitudinal direction L and the lateral direction T (FIG. 2), e.g., in one or more planes parallel to the X-Y plane and, thus, parallel to the mounting surface 20.

As described herein, one or more ports 108 may be exposed on the lower surface 106 of the first component 102a in the vertical component stack 100. Each port 108 exposed on the lower surface 106 of the first component 102a may be in contact with a contact area 22 on the mounting surface 20 of the device 10, e.g., to electrically connect the vertical component stack 100 with the device 10. It will be appreciated that the contact area 22 may be any suitable material, such as a conductive material, for electrically connecting the components 102 and the device 10.

In some embodiments, the contact area 22 is a plurality of separate contact areas 22, such as the first contact area 22a and the second contact area 22b shown in FIGS. 1 and 4. For instance, the plurality of separate contact areas 22 may include a separate contact area 22 corresponding to a respective one port 108, e.g., each port 108 may contact a separate contact area 22. In other embodiments, multiple ports 108 may contact the same contact area 22, e.g., each input 108a may connect with the same contact area 22.

The assembly 50 may also include one or more switches 24 or other device components 26, which may be fully or partially embedded in, or otherwise attached to or mounted on, the device 10 and electrically connected to one or more components 102 of the vertical component stack 100. For instance, as shown in FIGS. 1 and 4, a switch 24 of the device 10 may be electrically connected to a respective one component 102 of the vertical component stack 100 through a contact area 22. A device component 26, such as an external capacitor or resistor, an amplifier input, an antenna output, a microprocessor, etc., may be electrically connected to one or more components 102 of the vertical component stack 100 through a contact area 22.

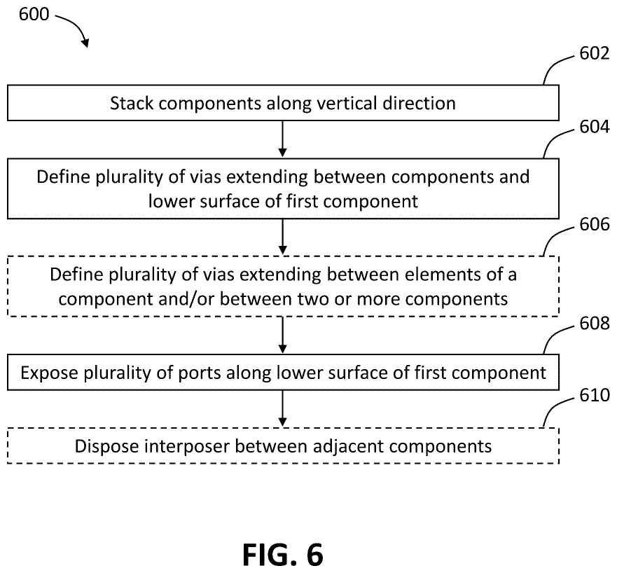

Turning to FIG. 6, an exemplary method 600 for forming a vertical component stack 100 includes (602) stacking a plurality of components 102 along a vertical direction V, e.g., such that a lower surface 106 of a second component 102b is disposed over an upper surface 104 of a first component 102a, which may be the bottommost component 102 in the vertical component stack 100. The method 600 further includes (604) defining a plurality of vias 110, each via 110 extending between a respective one component 102 and a lower surface 106 of the first component 102a. The method 600 optionally includes (606) defining one or more vias 112, e.g., to connect elements of a single component 102 or to interconnect two or more components 102 as described herein.

The method 600 also includes (608) exposing a plurality of ports 108 along the lower surface 106 of the first component 102a, which in some embodiments may include exposing one or more inputs 108a, outputs 108b, and grounds 108c. Each via 110 can extend between a respective one component 102 and a respective one port 108, e.g., to electrically connect a respective component 102 with a port 108 exposed on the lower surface 106 of the first component 102a. Thus, as described above, each of the plurality of vias 110 can extend through the first component 102a to electrically connect a respective component 102 with at least one port 108 exposed along the lower surface 106 of the first component 102a. Further, it will be appreciated that, in embodiments including at least one input 108a, at least one output 108b, and/or at least one ground 108c, (604) defining the plurality of vias 110 includes defining an input via 110a to electrically connect the at least one input 108a with a respective component 102, defining an output via 110b to electrically connect the at least one output 108b with a respective component 102, and/or defining a ground via 110c to electrically connect the at least one ground 108c with a respective component 102.

Referring still to FIG. 6, the method 600 optionally includes (610) disposing an interposer 114 between adjacent components 102 such that at least two adjacent components 102 are separated from one another by an interposer 114. As described above, in some embodiments, (606) disposing an interposer 114 between components 102 may include disposing an interposer 114 between each adjacent pair of components 102 of the plurality of components 102 of the vertical component stack 100, such that each component 102 is separated from an adjacent component 102 by an interposer 114.

### II. Vertically Oriented Component Stack and Assembly

Generally, a vertically oriented component stack includes a plurality of components that are stacked along a lateral direction such that at least a portion of each component in the stack is aligned in a longitudinal direction and a vertical direction. For example, the vertically oriented component stack may define a longitudinal direction, a lateral direction, and a vertical direction that are orthogonal to one another, and include a plurality of components. Each component of the plurality of components may include a first side surface opposite a second side surface along the vertical direction and a first end surface opposite a second end surface along the longitudinal direction. The first side surface and the second side surface each extend along the longitudinal direction from the first end surface to the second end surface. Further, each component of the plurality of components may have a first external termination formed on the first side surface and a second external termination formed on the first side surface. The first external termination may be spaced apart from the second external termination along the longitudinal direction. The plurality of components can be stacked along the lateral direction such that the first external terminations of the plurality of components are generally aligned with one another along the lateral direction and the second external terminations of the plurality of components are generally aligned with one another along the lateral direction.

The vertically oriented component stack may be disposed on a mounting surface of a device, such as a printed circuit board (PCB) or the like, with the first external termination and the second external termination adjacent the mounting surface and electrically connected to the device, to form a vertically oriented component stack assembly.

The present inventors have discovered that such a vertically oriented component stack, with components terminated along the same edge or surface, allows the components to stand up vertically when connected to a device, such as a PCB. Such side termination can allow multiple components to be stacked together into a vertically oriented component stack or a bank that occupies minimal space on the device, e.g., a bank of vertically oriented components occupies less board space, or has a smaller footprint, than similar devices with end terminations and internal conductive layers that extend parallel to the board. For example, the thickness of each component in the bank, which usually is less than or smaller than the length and width of a component, and the length of each component in the bank can define the footprint area of the vertically oriented component stack or bank, which is less than the footprint area defined by the length and width of each component (which usually are larger or greater than the thickness). Moreover, the vertically oriented stack or bank may be connected to a board, etc. using shorter pathways than traditional layouts, which can prevent losses and improve overall performance at high frequencies.

In some embodiments, at least one component of the plurality of components includes a ground external termination formed on the first side surface of the at least one component. For example, the ground external termination may be disposed between the first external termination and the second external termination along the longitudinal direction.

The external terminations formed on the first side surface of each component (e.g., the first and second external terminations and, in some embodiments, the ground terminations) may be formed using one or more of a variety of techniques generally known in the art. For instance, the external terminations could be formed using a solder fillet, wrapping, plating, and/or drilling or otherwise defining breaks in a solid bar of termination material. As further examples, the external terminations may be formed using techniques such as sputtering, painting, printing, electroless plating or fine copper terminal (FCT), electroplating, plasma deposition, propellant spray/air brushing, and so forth.

In general, the external terminations may be formed from any of a variety of different materials as is known in the art. For instance, the external terminations may be made from a metal, such as a conductive metal. The external termination materials may include precious metals (e.g., silver, gold, palladium, platinum, etc.), base metals (e.g., copper, tin, nickel, chrome, titanium, tungsten, etc.), and so forth, as well as various combinations thereof. In one particular embodiment, the external terminations may comprise copper or an alloy thereof.

In one embodiment, the external terminations may be formed such that the external terminations are relatively thick. For instance, the external terminations may be formed by applying a thick film stripe of a metal to exposed portions of electrode layers (e.g., by dipping the capacitor in a liquid external termination material). Such metal may be in a glass matrix and may include silver or copper. As an example, such strip may be printed and fired onto the capacitor. Thereafter, additional plating layers of metal (e.g., nickel, tin, solder, etc.) may be created over the terminal strips such that the capacitor is solderable to a substrate. Such application of thick film stripes may be conducted using any method generally known in the art (e.g., by a terminal machine and printing wheel for transferring a metal-loaded paste over the exposed electrode layers).

The thick-plated external terminations may have an average thickness of about 150 μm or less, such as about 125 μm or less, such as about 100 μm or less, such as about 80 μm or less. The thick-plated external terminations may have an average thickness of about 25 μm or more, such as about 35 μm or more, such as about 50 μm or more, such as about 75 or more μm. For instance, the thick-plated external terminations may have an average thickness of from about 25 μm to about 150 μm, such as from about 35 μm to about 125 μm, such as from about 50 μm to about 100 μm.

In another embodiment, the external terminations may be formed such that each external termination is a thin-film plating of a metal. Such thin-film plating can be formed by depositing a conductive material, such as a conductive metal, on an exposed portion of an electrode layer. For instance, a leading edge of an electrode layer may be exposed such that it may allow for the formation of a plated terminal.

The thin-plated external terminations may have an average thickness of about 50 μm or less, such as about 40 μm or less, such as about 30 μm or less, such as about 25 μm or less. The thin-plated external terminations may have an average thickness of about 5 μm or more, such as about 10 μm or more, such as about 15 μm or more. For instance, the external terminations may have an average thickness of from about 5 μm to about 50 μm, such as from about 10 μm to about 40 μm, such as from about 15 μm to about 30 μm, such as from about 15 μm to about 25 μm.

In some embodiments, the external terminations may comprise a plated terminal, such as an electroplated terminal, an electroless plated terminal, or a combination thereof. For instance, an electroplated terminal may be formed via electrolytic plating. An electroless plated terminal may be formed via electroless plating.

When multiple layers constitute the external termination, the external termination may include an electroplated terminal and an electroless plated terminal. For instance, electroless plating may first be employed to deposit an initial layer of material. The plating technique may then be switched to an electrochemical plating system, which may allow for a faster buildup of material.

When forming plated external terminations with either plating method, an edge of one or more electrode layers or internal conductive layers of the component may be exposed from the body of the component and subjected to a plating solution, e.g., by dipping the component into the plating solution. The plating solution may contain a conductive material, such as a conductive metal, to form the plated termination, i.e., the conductive material is employed to form the plated terminal. Such conductive material may be any of the aforementioned materials or any as generally known in the art. For instance, the plating solution may be a nickel sulfamate bath solution or other nickel solution such that the plated layer and external termination comprise nickel. Alternatively, the plating solution may be a copper acid bath or other suitable copper solution such that the plated layer and external termination comprise copper.

Additionally, it should be understood that the plating solution may comprise other additives as generally known in the art. For instance, the additives may include other organic additives and media that can assist in the plating process. Additionally, additives may be employed in order to employ the plating solution at a desired pH. In one embodiment, resistance-reducing additives may be employed in the solutions to assist with complete plating coverage and bonding of the plating materials to the capacitor and exposed leading edges of the lead tabs.

The component may be exposed, submersed, or dipped in the plating solution for a predetermined amount of time. Such exposure time is not necessarily limited but may be for a sufficient amount of time to allow for enough plating material to deposit in order to form the plated terminal. In this regard, the time should be sufficient for allowing the formation of a continuous connection among the desired exposed, adjacent leading edges of lead tabs of a given polarity of the respective electrode layers within a set of alternating dielectric layers and electrode layers.

In general, the difference between electrolytic plating and electroless plating is that electrolytic plating employs an electrical bias, such as by using an external power supply. Typically, the electrolytic plating solution may be subjected to a high current density range, for example, ten to fifteen amp/ft² (rated at 9.4 volts). A connection may be formed with a negative connection to the capacitor requiring formation of the plated terminals and a positive connection to a solid material (e.g., Cu in Cu plating solution) in the same plating solution. That is, the capacitor is biased to a polarity opposite that of the plating solution. Using this method, the conductive material of the plating solution is attracted to the metal of the exposed leading edge of the lead tabs of the electrode layers.

Prior to submersing or subjecting the component to a plating solution, various pretreatment steps may be employed. These steps may be conducted for a variety of purposes, including to catalyze, to accelerate, and/or to improve the adhesion of the plating materials to the edges of the one or more electrodes or internal conductive layers of the component.

Additionally, prior to plating or any other pretreatment steps, an initial cleaning step may be employed. This step may be employed to remove any oxide buildup that forms on the exposed layers of the component. This cleaning step may be particularly helpful to assist in removing any buildup of nickel oxide when the internal electrodes or other conductive elements are formed of nickel. Component cleaning may be effected by full immersion in a preclean bath, such as one including an acid cleaner. In one embodiment, exposure may be for a predetermined time, such as on the order of about 10 minutes. Cleaning may also alternatively be effected by chemical polishing or harperizing steps.

In addition, a step to activate the exposed metallic edges of the electrode layers or other internal conductive layers may be performed to facilitate depositing of the conductive materials. Activation can be achieved by immersion in palladium salts, photo patterned palladium organometallic precursors (via mask or laser), screen printed or ink-jet deposited palladium compounds or electrophoretic palladium deposition. It should be appreciated that palladium-based activation is presently disclosed merely as an example of activation solutions that often work well with activation for exposed tab portions formed of nickel or an alloy thereof. However, it should be understood that other activation solutions may also be utilized.

Also, in lieu of or in addition to the aforementioned activation step, the activation dopant may be introduced into the conductive material when forming the electrode or conductive layers of the component. For instance, when the electrode or conductive layer comprises nickel and the activation dopant comprises palladium, the palladium dopant may be introduced into the nickel ink or composition that forms the electrode or conductive layers. Doing so may eliminate the palladium activation step. It should be further appreciated that some of the above activation methods, such as organometallic precursors, also lend themselves to co-deposition of glass formers for increased adhesion to, e.g., a generally ceramic body of some embodiments of the components of the vertically oriented component stack. When activation steps are taken as described above, traces of the activator material may often remain at the exposed conductive portions before and after terminal plating.

Additionally, post-treatment steps after plating may also be employed. Such steps may be conducted for a variety of purposes, including enhancing and/or improving adhesion of the materials. For instance, a heating (or annealing) step may be employed after performing the plating step. Such heating may be conducted via baking, laser subjection, UV exposure, microwave exposure, arc welding, etc.

As indicated herein, an external termination may include at least one plating layer. In one embodiment, the external terminations may comprise only one plating layer. However, it should be understood that the external terminations may comprise a plurality of plating layers. For instance, the external terminations may comprise a first plating layer and a second plating layer. In addition, the external terminations may also comprise a third plating layer. The materials of these plating layers may be any of the aforementioned and as generally known in the art.

For instance, one plating layer, such as a first plating layer, may comprise copper or an alloy thereof. Another plating layer, such as a second plating layer, may comprise nickel or an alloy thereof. Another plating layer, such as a third plating layer, may comprise tin, lead, gold, or a combination of materials, such as an alloy. Alternatively, an initial plating layer may include nickel, followed by plating layers of tin or gold. In another embodiment, an initial plating layer of copper may be formed and then a nickel layer.

In one embodiment, an initial or first plating layer may be a conductive metal (e.g., copper). This area may then be covered with a second layer containing a resistor-polymeric material for sealing. The area may then be polished to selectively remove resistive polymeric material and then plated again with a third layer containing a conductive, metallic material (e.g., copper).

The aforementioned second layer above the initial plating layer may correspond to a solder barrier layer, for example a nickel-solder barrier layer. In some embodiments, the aforementioned layer may be formed by electroplating an additional layer of metal (e.g., nickel) on top of an initial electrolessly or electrolytically plated layer (e.g., plated copper). Other exemplary materials for the aforementioned solder barrier layer include nickel-phosphorus, gold, and silver. A third layer on the aforementioned solder-barrier layer may in some embodiments correspond to a conductive layer, such as plated Ni, Ni/Cr, Ag, Pd, Sn, Pb/Sn or other suitable plated solder.

In addition, a layer of metallic plating may be formed followed by an electroplating step to provide a resistive alloy or a higher resistance metal alloy coating, for example, electroless Ni—P alloy over such metallic plating. It should be understood, however, that it is possible to include any metal coating as those of ordinary skill in the art will understand from the complete disclosure herewith.

It should be appreciated that any of the aforementioned steps can occur as a bulk process, such as barrel plating, fluidized bed plating, and/or flow-through plating terminal processes, all of which are generally known in the art. Such bulk processes enable multiple components to be processed at once, providing an efficient and expeditious termination process. This is a particular advantage relative to conventional termination methods, such as the printing of thick-film terminations that require individual component processing.

In some embodiments, a combination of external termination configurations may be used for the external terminations of one or more components of a vertically oriented component stack. For example, in some embodiments, the first and second external terminations may be a combination of FCT (fine copper termination) and thick film terminations. For instance, an FCT may be applied on each end of the first side surface of a component, and a thick film termination may be applied over each FCT termination. Other combinations of termination formation techniques and/or configurations may be used as well.

As described herein, the formation of the external terminations is generally guided by the position of the exposed edges of electrode layers or other conductive layers of a component. Such phenomena may be referred to as “self-determining” because the formation of the external plated terminals is determined by the configuration of the exposed conductive material at the selected locations on the component. In some embodiments, a component may include “dummy tabs” to provide exposed conductive metal along portions of the body of the component that does not include electrodes or conductive layers that extend to an edge of the component body. In some embodiments, one or more “dummy tabs,” “dummy electrodes,” anchor tabs, and/or anchor electrodes may, e.g., be added features for a nucleate function occurring such as during an FCT (fine copper termination, electroless plating) process. Such dummy or anchor tabs or electrodes may be positioned internally or externally relative to the component to nucleate metallized plating material to form external plated terminals in an FCT process.

It should be appreciated that additional technologies for forming external terminations may also be within the scope of the present disclosure. Exemplary alternatives include, but are not limited to, formation of external terminations (such as the first, second, and/or ground external terminations) by plating, magnetism, masking, electrophoretics/electrostatics, sputtering, vacuum deposition, printing, or other techniques for forming both thick-film or thin-film conductive layers.

In addition to the first side surface and the second side surface, each component of the plurality of components may include a third side surface opposite a fourth side surface. The third side surface and the fourth side surface may extend from the first end surface to the second surface along the longitudinal direction and from the first side surface to the second side surface along the vertical direction. In some embodiments, the first external termination of at least one component of the plurality of components wraps around a first end of the component such that a first portion of the first external termination is formed on the first side surface, a second portion of the first external termination is formed on the first end surface, a third portion of the first external termination is formed on the third side surface, and a fourth portion of the first external termination is formed on the fourth side surface. In some embodiments, the second external termination of at least one component of the plurality of components wraps around a second end of the component such that a first portion of the second external termination is formed on the first side surface, a second portion of the second external termination is formed on the second end surface, a third portion of the second external termination is formed on the third side surface, and a fourth portion of the second external termination is formed on the fourth side surface.

In some embodiments, one or both of the first or second external terminations may partially wrap around the respective end of a respective component. For example, in some embodiments, the second portion of the first external termination and the second portion of the second external termination of each component of the plurality of components that wraps to the first end surface and the second end surface, respectively, is spaced apart from the third side surface and the fourth side surface along the lateral direction.

In embodiments including at least one component having a ground external termination disposed between the first and second external terminations, the ground external termination may wrap from the first side surface to one of the third side surface or the fourth side surface or both of the third side surface and the fourth side surface.

The vertically oriented component stack may include any suitable number of components stacked along the lateral direction. For example, in some embodiments, the vertically oriented component stack includes at least three components stacked along the lateral direction, such as three, four, five, six, seven, or more components stacked along the lateral direction. In embodiments including only three components, a first component and a third component may be the outermost components in the vertically oriented component stack, with a second component sandwiched between the first component and the third component in the lateral direction. In embodiments including more than three components, two or more components may be sandwiched between the two outermost components.

In some embodiments, the vertically oriented component stack includes at least one filter. For example, at least one component of the plurality of components in the stack may be a filter. The at least one filter may be any suitable filter type, such as a thin-film filter or a multilayer filter, which may be configured as described above, or any other suitable filter. For example, the filter may include a signal path having an input and an output. The filter may be configured to filter signals from the input and produce a filtered output signal at the output. In some embodiments, a plurality of dielectric layers may have conductive layers formed thereon that are selectively shaped or patterned to form capacitors and/or inductors that, when stacked together, form the filter. The input port and the output port may be terminated on the same side, e.g., along the first side surface of the filter component. For instance, the first external termination may be an input port of the filter and the second external termination may be an output port of the filter. Further, as described herein, the filter may include a ground external termination that is a ground port of the filter.

In some embodiments, one or more vias may be formed in a single component of the vertically oriented component stack, e.g., where a component of the stack is a filter, a via may be formed therein to connect two or more elements of the filter. In some embodiments, one or more vias may be formed to interconnect components within the vertically oriented component stack. For instance, a via formed in one component may contact a via formed in an adjacent component to electrically connect the adjacent components. Suitable techniques and materials for forming vias in one or more components of the vertically oriented component stack are described more fully elsewhere herein, e.g., with respect to the vertical component stack described above.

In some embodiments, an interposer is disposed between at least one adjacent pair of components of the plurality of components of the vertically oriented component stack. For instance, an interposer may be disposed between the first component of the plurality of components and the second component of the plurality of components. In some embodiments, the vertically oriented component stack includes a plurality of interposers, with a respective one interposer of the plurality of interposers disposed between each adjacent pair of components of the plurality of components. An interposer between an adjacent pair of components may electrically isolate the components of the adjacent pair of components from one another, which may improve the performance of the vertically oriented component stack. For example, an interposer between adjacent components provides electrical separation between adjacent terminations of the stacked components. As described above, each interposer may be formed from a suitable material, and in some embodiments, the interposer includes a substrate comprising aluminum, such as aluminum nitride (AlN). In embodiments not including an interposer between each adjacent pair of components, a cover formed from aluminum nitride or other electrically insulating material may be disposed over the components to create space between adjacent external terminations.

The vertically oriented component stack may be configured for mounting on a mounting surface of a device to form an assembly, e.g., a vertically oriented component stack assembly. The assembly may include a device having a mounting surface, such as a printed circuit board (PCB) or the like, and a vertically oriented component stack such as described herein. The mounting surface may extend in a mounting plane that is parallel to an X-Y plane defined by the longitudinal direction and the lateral direction. The first side surface of each component of the plurality of components of the vertically oriented component stack may extend in a first plane parallel to the X-Y plane, and the vertically oriented component stack may be disposed on the mounting surface such that the first plane of each component of the plurality of components is parallel to the mounting plane. Further, the vertically oriented component stack may be disposed on the mounting surface such that the first side surface of each component of the plurality of components extends parallel to the mounting surface and the first external termination and the second external termination of each component of the plurality of components is in contact with the mounting surface.

As described herein, at least one external termination is disposed on the first side surface of each component of the vertically oriented component stack. For example, a first external termination, a second external termination, and a ground termination may each be formed on the first side surface of each component of the vertically oriented component stack. In some embodiments, when mounted on the mounting surface of the device, each external termination of the vertically oriented component stack may be in contact with a contact area on the mounting surface of the device, e.g., to electrically connect the vertically oriented component stack with the device.

In some embodiments, one or more components of the plurality of components of the vertically oriented component stack includes at least one internal conductive layer. The internal conductive layer may extend in the vertical direction and the longitudinal direction such that the internal conductive layer is perpendicular to the mounting surface when the stack is mounted on the mounting surface of the device. The internal conductive layer may be, for example, an inductor, an electrode of a capacitor, a patterned conductive line, etc.

In some embodiments, the contact area of the device is a plurality of separate contact areas, and the plurality of separate contact areas includes a separate contact area corresponding to a respective one external termination. For example, the plurality of separate contact areas may include a separate contact area corresponding to a respective one first external termination, second external termination, and ground termination of the plurality of components of the stack.

The assembly may also include one or more switches, e.g., fully or partially embedded in, or otherwise attached to or mounted on, the device and electrically connected to the plurality of components of the vertically oriented component stack. For instance, a switch of the device may be electrically connected to a respective one component of the plurality of components of the vertically oriented component stack. The one or more switches can allow selective enablement of components of the vertically oriented component stack. For example, the one or more switches may allow one or more components of the vertically oriented component stack to be selectively activated and deactivated, e.g., based on an operating frequency range, a desired performance characteristic, a power or other load, thermal or heat management, and/or other operational needs or goals.

The present disclosure also provides methods for forming a vertically oriented component stack such as described herein. The present disclosure may also provide methods for forming an assembly having a device and a vertically oriented component stack disposed thereon, as well be appreciated by those having ordinary skill in the art based on the present disclosure.

A method for forming a vertically oriented component stack may include forming a first external termination on a first side surface of one or more components of a plurality of components, the first side surface opposite a second side surface along the vertical direction and the first side surface and the second side surface each extending along the longitudinal direction from a first end surface to a second end surface that is opposite the first end surface along the longitudinal direction. The method may further include forming a second external termination on the first side surface of one or more components of the plurality of components. In some embodiments, the method can include forming a ground external termination on the first side surface of one or more components of the plurality of components. The ground external termination may be disposed between the first external termination and the second external termination along the lateral direction. It will be appreciated that forming the one or more external terminations (whether a first external termination, a second external termination, or a ground external termination) may include one or more of the techniques described above for forming external terminations, such as forming a solder fillet, wrapping a conductive material about the component such that the conductive material is disposed over two or more surfaces of the component, plating (e.g., electroless plating, FCT electroplating, etc.), forming breaks in a solid bar of termination material, sputtering, and/or any of the other techniques described herein.

The method may also include stacking the plurality of components along the lateral direction such that the first external terminations of the plurality of components are generally aligned with one another along the lateral direction and the second external terminations of the plurality of components are generally aligned with one another along the lateral direction. When components in the stack also include ground external terminations, the ground external terminations may be generally aligned with one another along the lateral direction.

### Example Embodiments

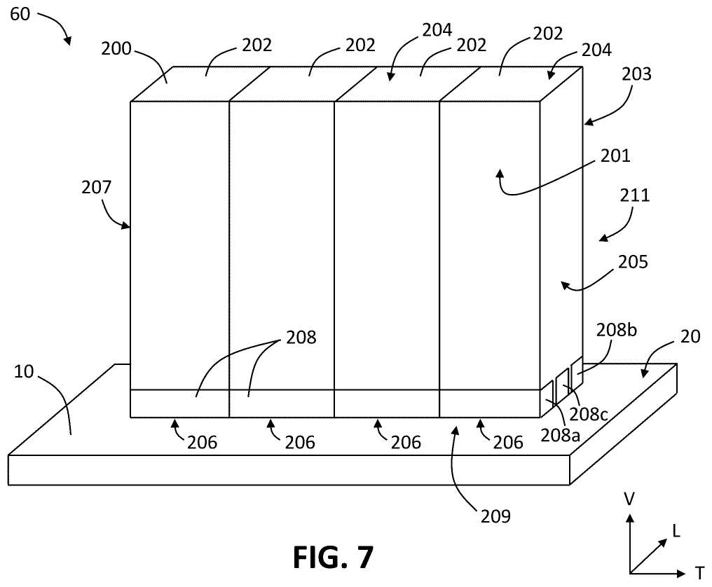

Referring now to FIGS. 7 through 12, example embodiments of the vertically oriented component stack, the vertically oriented component stack assembly, and methods for forming a vertically oriented component stack will be described in greater detail. It will be appreciated that the use of similar reference numerals as used with respect to the vertical component stack assembly 50 and the vertical component stack 100 may denote the same or similar features.

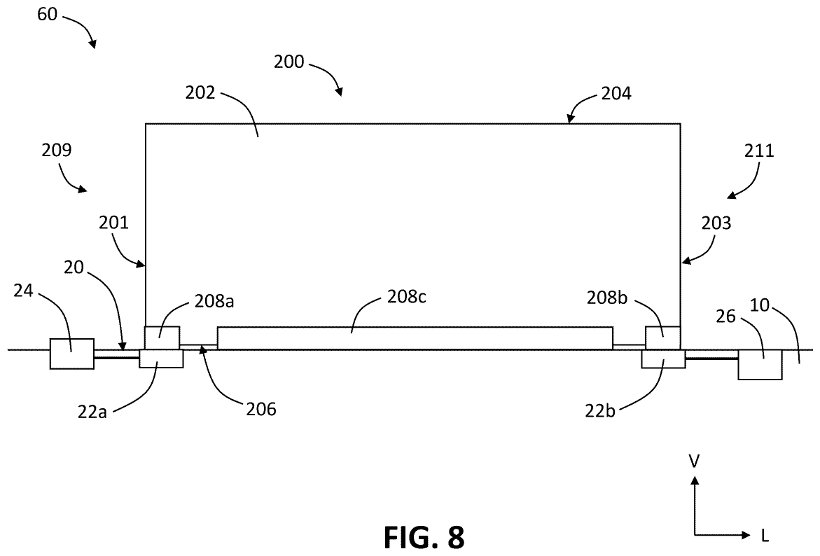

As illustrated in FIG. 7, which provides a schematic perspective view of a vertically oriented component stack assembly 60, the assembly 60 includes a vertically oriented component stack 200 disposed on a mounting surface 20 of a device 10. It will be appreciated that the device 10 may be a printed circuit board (PCB) or the like and may be configured as described above with respect to FIGS. 1 and 4. FIG. 8 provides a side view of the vertically oriented component stack assembly 60.

In the illustrated embodiment, the vertically oriented component stack 200 has four components 202 stacked along a lateral direction T, which is orthogonal to a longitudinal direction L and a vertical direction V. It will be appreciated that, in other embodiments, other numbers of components 202 may be stacked together along the lateral direction T to form the vertically oriented component stack 200, which also may be referred to as a vertically oriented component bank. For example, three, five, six, or more components 202 may be stacked together to form the stack or bank 200.

Each component 202 includes a plurality of external terminations 208, including a first external termination 208a, a second external termination 208b, and a ground external termination 208c, which are all formed on a first side surface 206 of a respective component 202. That is, each external termination 208 of the components 202 of the vertically oriented component stack 200 is formed on the same side of a respective component 202. In the depicted embodiment, each external termination 208 is formed on the first side surface 206, which is opposite a second side surface 204 along the vertical direction.

Each component 202 also defines a first end surface 201 opposite a second end surface 203 along the longitudinal direction L. The first side surface 206 and the second side surface 204 each extend along the longitudinal direction L from the first end surface 201 to the second end surface 203. Each component 202 further defines a third side surface 205 opposite a fourth side surface 207. The third side surface 205 and the fourth side surface 207 extend from the first end surface 201 to the second surface 203 along the longitudinal direction L and from the first side surface 206 to the second side surface 204 along the vertical direction V. The first side surface 206 and the second side surface 204 may further extend from the third side surface 205 to the fourth side surface 207 along the lateral direction T.

The vertically oriented component stack 200 may be disposed on the mounting surface 20 of the device 10 such that one or more of the components 202 are electrically connected to the device 10 as described herein. More particularly, as shown in FIGS. 7 and 8, the first side surface 206 is positioned in contact with the mounting surface 20 such that the first external termination 208a, the second external termination 208b, and the ground external termination 208c contact a contact area 22 (FIG. 8) of the device 10 to electrically connect the components 202 of the vertically oriented component stack 200 with the device 10. It will be appreciated that the contact area 22 may be any suitable material, such as a conductive material, for electrically connecting the components 202 and the device 10.

In some embodiments, the contact area 22 is a plurality of separate contact areas 22, such as the first contact area 22a and the second contact area 22b shown in FIG. 8. For instance, the plurality of separate contact areas 22 may include a separate contact area 22 corresponding to a respective one first external termination 208a, a respective one second external termination 208b, and a respective one ground external termination 208c of the plurality of components 202, e.g., each external termination 208 may contact a separate contact area 22. In other embodiments, multiple external terminations 208a, 208b, 208c may contact the same contact area 22, e.g., each first external termination 208a of the vertically oriented component stack 200 may connect with the same contact area 22.

The assembly 60 may also include one or more switches 24 or other device components 26, which may be fully or partially embedded in, or otherwise attached to or mounted on, the device 10 and electrically connected to one or more components 202 of the vertically oriented component stack 200. For instance, as shown in FIG. 8, a switch 24 of the device 10 may be electrically connected to a respective one component 202 of the vertically oriented component stack 200 through a contact area 22. Similarly, one or more device components 26, such as an external capacitor or resistor, an amplifier input, an antenna output, a microprocessor, etc., may be electrically connected to one or more components 202 of the vertically oriented component stack 200 through one or more contact areas 22.

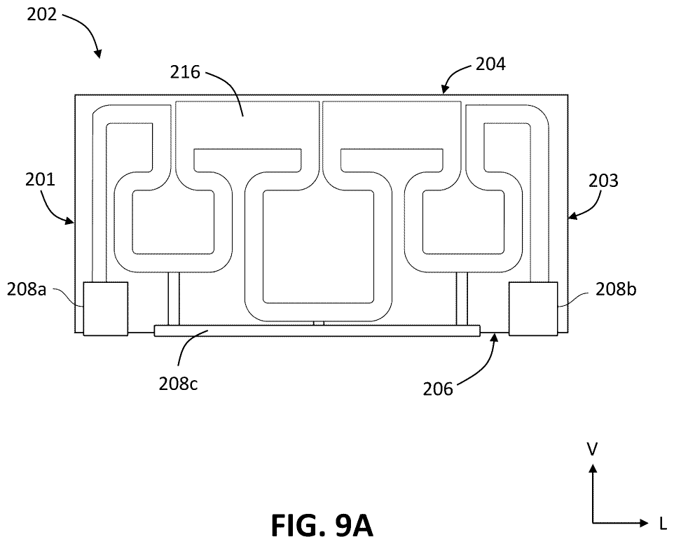

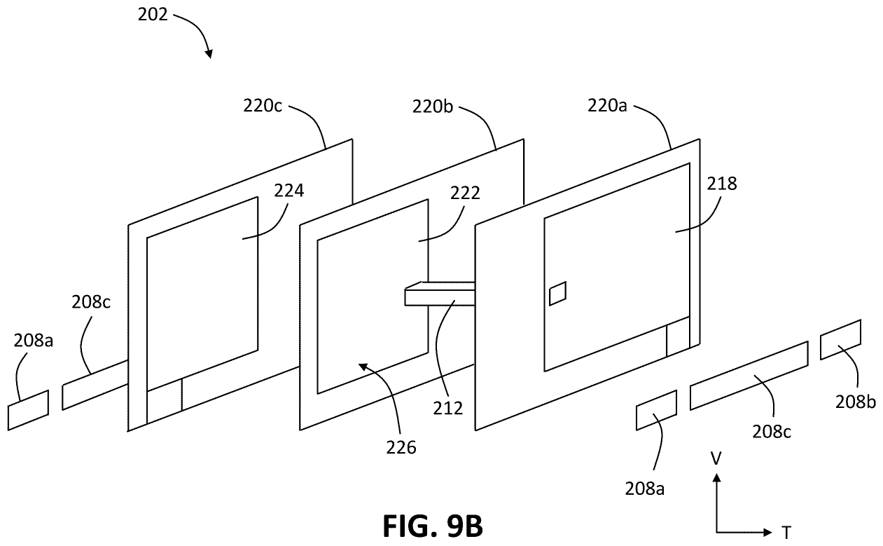

Referring now to FIGS. 9A and 9B, in some embodiments, at least one component 202 in the vertically oriented component stack 200 is a filter. The at least one filter may be any suitable filter type, such as a thin-film filter as shown in FIG. 9A, a multilayer filter as shown in FIG. 9B, or any other suitable filter. For example, referring to FIG. 9A, at least one component 202 may be a thin-film filter having an inductor including a patterned conductive line 216 extending between a first external termination 208a, which may be an input port of the filter, and a second external termination 208b, which may be an output port of the filter. As described elsewhere herein, the patterned conductive line 216 may include at least one full loop (such as three loops as shown in FIG. 9A) or one or more partial loops, although straight line segments also may be used to define one or more inductors. The patterned conductive line 216 is also electrically connected to a ground external terminal 208c.

FIG. 9B provides an exploded view of a plurality of layers of a multilayer filter, which are stacked along the lateral direction T to form the filter. For example, at least one component 202 of the vertically oriented component stack 200 may be a multilayer filter as shown in FIG. 9B, having a conductive layer formed over a first dielectric layer 220a to define an inductor 218, and a first electrode 222 formed over a second dielectric layer 220b and a second electrode 224 formed over a third dielectric layer 220c to define a capacitor 226. The inductor 218 is electrically connected to a first external termination 208a, which may be an input port of the filter, and to the capacitor 226 using a via 212, and the capacitor 226 is electrically connected to a second external termination 208b, which may be an output port of the filter, e.g., to form a signal path from the input or first external termination 208a to the output or second external termination 208b. Although not illustrated in FIG. 9B, it will be appreciated that one or both of the inductor 218 or capacitor 226 also may be connected with ground external terminations 208c.

It will be appreciated that the filter elements shown in FIGS. 9A and 9B are by way of example only, and each filter component 202 included in the vertically oriented component stack 200 may be configured as needed based on, e.g., filter type (e.g., low-pass, high-pass, or passband), characteristic frequency (e.g., 6 GHZ, 8 GHZ, 12 GHz, or a higher or a lower characteristic frequency), etc.

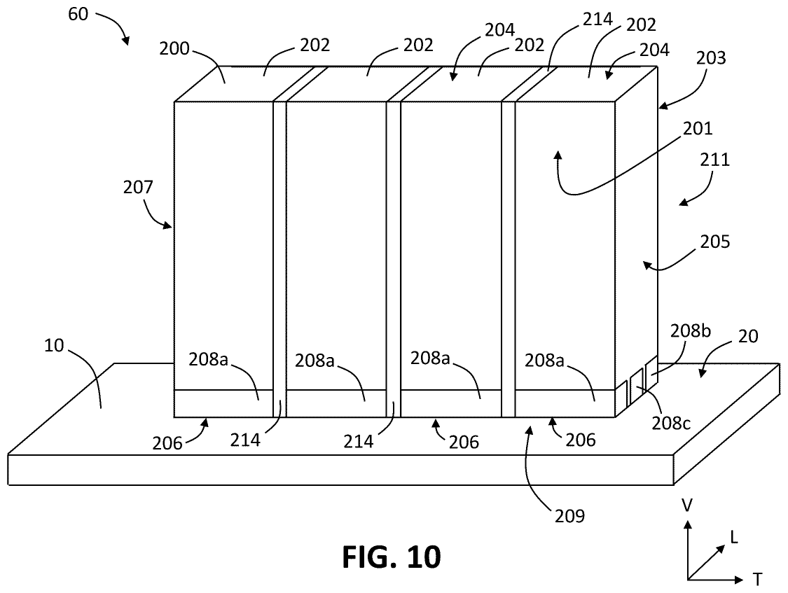

Turning to FIG. 10, a schematic side view is provided of another embodiment of the vertically oriented component stack 200 and assembly 60. In the embodiment depicted in FIG. 10, an interposer 214 is disposed between each adjacent pair of components 202. More particularly, an interposer 214 is disposed between a first component 202a and a second component 202b, another interposer 214 is disposed between the second component 202b and a third component 202c, and still another interposer 214 is disposed between the third component 202c and a fourth component 202d. Although not illustrated in FIG. 10, it will be appreciated that one or more vias 212 connecting components 202 in the stack 200 to one another may pass through an interposer 214 as needed to connect the components 202 to one another.

As shown in FIGS. 7 and 10, in some embodiments, the first external termination 208a of at least one component 202 of the stack 200 wraps around a first end 209 of the component 202 such that a first portion 208a-1 of the first external termination 208a is formed on the first side surface 206, a second portion 208a-2 of the first external termination 208a is formed on the first end surface 201, a third portion 208a-3 of the first external termination 208a is formed on the third side surface 205, and a fourth portion 208a-4 of the first external termination 208a is formed on the fourth side surface 207. Similarly, in some embodiments, the second external termination 208b of at least one component 202 of the stack 200 wraps around a second end 211 of the component 202 such that a first portion 208b-1 of the second external termination 208b is formed on the first side surface 206, a second portion 208b-2 of the second external termination 208b is formed on the second end surface 203, a third portion 208b-3 of the second external termination 208b is formed on the third side surface 205, and a fourth portion 208b-4 of the second external termination 208b is formed on the fourth side surface 207.

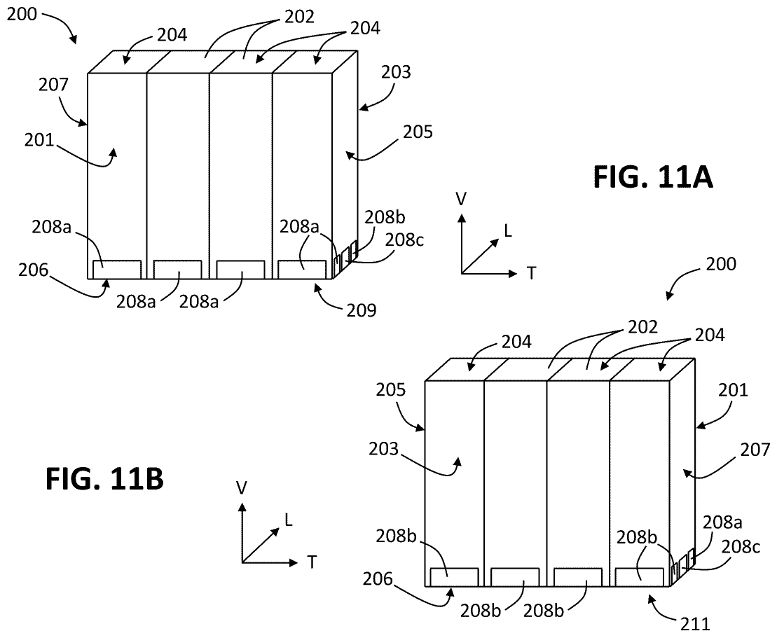

Referring now to FIGS. 11A and 11B, in some embodiments, at least one of the first or second external terminations 208a, 208b may partially wrap around the respective end 209, 211 of a respective component 202. For example, as shown in FIG. 11A, the second portion 208a-2 of the first external termination 208a of each component 202 of the plurality of components that wraps to the first end surface 201 is spaced apart from the third side surface 205 and the fourth side surface 207 along the lateral direction T. As depicted in FIG. 11B, the second portion 208b-2 of the second external termination 208b of each component 202 of the plurality of components that wraps to the second end surface 203 is spaced apart from the third side surface 205 and the fourth side surface 207 along the lateral direction T.

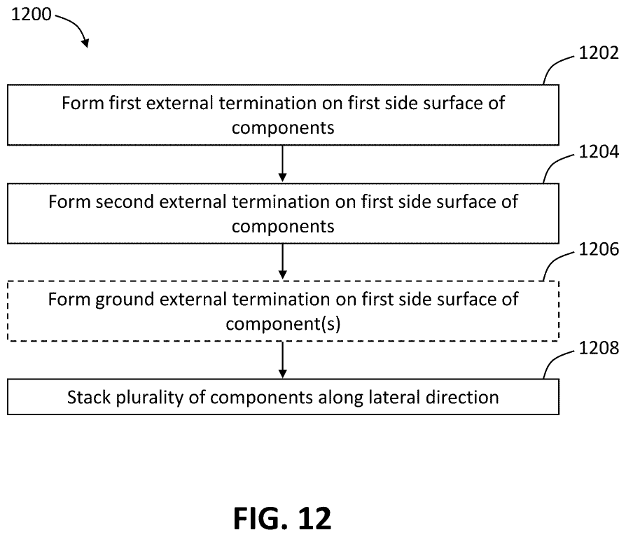

Turning to FIG. 12, an exemplary method 1200 for forming a vertically oriented component stack 200 includes (1202) forming a first external termination 208a on a first side surface 206 of a plurality of components 202. One or more of the components 202 may be filter as described herein. The method 1200 also includes (1204) forming a second external termination 208b on the first side surface 206 of the plurality of components 202. Optionally, the method 1200 includes (1206) forming a ground external termination 208c on the first side surface 206 of one or more of the plurality of components 202. As such, each external termination 208 (e.g., first external terminations 208a, second external terminations 208b, and, when formed on one or more components, ground external terminations 208c) formed on the plurality of components 202 is formed along the same edge or surface of the components 202.

As shown at (1208) in FIG. 12, the method 1200 also includes stacking the plurality of components 202 along a lateral direction T. The stack of components 202 forms the vertically oriented component stack 200, which may be disposed or mounted on a device 10 as described herein to form a vertically oriented component stack assembly 60. As described herein, the components 202 of the vertically oriented component stack 200 are oriented perpendicular to a mounting surface 20 of the device 10, rather than parallel to a mounting surface as commonly practiced, such that the components 202 are vertically oriented and terminated along one side of the stack 200. Such a vertically oriented component stack 200 can occupy less space on the device 10 than typical components, thus providing a space-saving advantage over known designs. Other advantages, such as improved performance, also may be realized from stacking the components 202 into a component stack or bank 200 as described herein.

### III. Vertically Oriented Interposer Stack and Assembly

In general, a vertically oriented interposer stack includes a plurality of interposers that are stacked along a lateral direction with a component, such as a filter, disposed between adjacent interposers. At least a portion of each interposer in the stack may be aligned in a longitudinal direction and a vertical direction, and two or more of the components disposed between interposers may be aligned with one another in the longitudinal direction and the vertical direction. For example, the vertically oriented interposer stack may define a longitudinal direction, a lateral direction, and a vertical direction that are orthogonal to one another, and include a plurality of interposers and a plurality of components. Each interposer of the plurality of interposers may include a first side surface opposite a second side surface along the vertical direction and a first end surface opposite a second end surface along the longitudinal direction. The first side surface and the second side surface each extend along the longitudinal direction from the first end surface to the second end surface. Further, each interposer of the plurality of interposers may have a first external termination formed on the first side surface and a second external termination formed on the first side surface. The first external termination may be spaced apart from the second external termination along the longitudinal direction. At least one component of the plurality of components may be disposed between adjacent interposers. The plurality of interposers, with components therebetween that may be electrically connected with the interposers, can be stacked along the lateral direction such that the first external terminations of the plurality of interposers are generally aligned with one another along the lateral direction and the second external terminations of the plurality of interposers are generally aligned with one another along the lateral direction.

The vertically oriented interposer stack may be disposed on a mounting surface of a device, such as a printed circuit board (PCB) or the like, with the first external termination and the second external termination adjacent the mounting surface and electrically connected to the device, to form a vertically oriented interposer stack assembly.

The present inventors have discovered that such a vertically oriented interposer stack, with interposers terminated along the same edge or surface, allows the interposers to stand up vertically when connected to a device, such as a PCB. Such side termination can allow multiple interposers to be stacked together into a vertically oriented interposer stack or a bank that occupies minimal space on the device, e.g., a bank of vertically oriented interposers occupies less board space, or has a smaller footprint, than similar devices with end terminations and internal conductive layers that extend parallel to the board.

Further, a conductive pattern may be deposited on a surface of each interposer such that the conductive pattern is electrically connected to the first external termination and the second external termination. The components disposed between adjacent interposers can be electrically connected with the conductive pattern such that the components are readily formed into a stack or bank (such as a filter stack or bank where the plurality of components are filters) when disposed between adjacent interposers. Such a configuration can simplify and reduce the costs of manufacturing the stack or bank, while also reducing board space occupied by the stack or bank and/or providing performance benefits as described herein. Further, such a configuration can allow generically designed components, such as generic thin film or multilayer filters, to be used in a component bank without specially designing the component bank for the individual components, e.g., such that existing discrete components can be used in a new configuration. Moreover, the vertically oriented interposer stack with patterned interposers can allow easy use of multiple different components in the stack, such as a mix of different filter technologies (e.g., both thin film and multilayer filters may be used in the stack) and/or a mix of different component types (e.g., a stack including a multilayer capacitor and a thin film filter, etc.).

As described above, each interposer may be formed from a suitable material. In some embodiments, each interposer includes a substrate comprising aluminum, such as aluminum nitride (AlN). Other suitable materials are described elsewhere herein.

As stated, at least one interposer of the plurality of interposers can include a conductive pattern deposited or formed on a surface of the at least one interposer. For example, the conductive pattern may be deposited or formed on a third side surface of the interposer, the third side surface extending along the longitudinal direction from the first end surface to the second end surface of the at least one interposer and extending along the vertical direction from the first side surface to the second side surface of the at least one interposer.

The conductive pattern may have any suitable shape or configuration and may be formed from any suitable conductive material, such as those conductive materials described herein. In some embodiments, a conductive pattern may be deposited or formed on a surface of each interposer of the plurality of interposers. The conductive pattern may have the same configuration on each interposer, or at least one conductive pattern may be different from other conductive patterns formed or deposited on the plurality of interposers of the vertically oriented interposer stack. For example, the conductive pattern may correspond to the component in electrical contact with the conductive pattern, such that different conductive patterns may be used for different components (e.g., the conductive pattern for a filter in electrical connection therewith may be different from a conductive pattern for a multilayer ceramic capacitor in electrical connection with the conductive pattern).

As described herein, at least one component of the plurality of components in the stack may be a filter. In some embodiments, the filter may be disposed between the at least one interposer having the conductive pattern and an adjacent interposer such that the filter is in electrical contact with the conductive pattern. The conductive pattern may include an input line and an output line, and the filter may be disposed in electrical contact with the input line and the output line. In some embodiments, the first external termination of the at least one interposer is an input port, and the second external termination of the at least one interposer is an output port. The input line may be connected with the input port and the output line may be connected with the output port. In such embodiments, the filter may be electrically connected with the conductive pattern of the at least one interposer to filter a signal between the input port and the output port.

In some embodiments, at least one component of the plurality of components disposed between interposers may be spaced apart from one or more sides and/or ends of an adjacent interposer. For instance, the at least one component may not extend along the entirety of a height in the vertical direction and/or a length in the longitudinal direction of the adjacent interposer. In some embodiments, the at least one component may be approximately centered with respect to a surface of an adjacent interposer without extending to any edge of the surface of the interposer. That is, the at least one component may be shorter in the vertical direction and in the longitudinal direction than the surface of the adjacent interposer, and the at least one component may be approximately centered with respect to the interposer surface such that the at least one component is spaced apart from the edges defining the interposer surface.

In some embodiments, at least one interposer of the plurality of interposers includes a ground external termination formed on the first side surface of the at least one interposer. For example, the ground external termination may be disposed between the first external termination and the second external termination along the longitudinal direction.

The external terminations formed on the first side surface of each interposer (e.g., the first and second external terminations and, in some embodiments, the ground terminations) may be formed using one or more of a variety of techniques generally known in the art. Such techniques may include, for example, forming a solder fillet, wrapping, plating, and/or drilling or otherwise defining breaks in a solid bar of termination material, as well as sputtering, painting, printing, electroless plating or fine copper terminal (FCT), electroplating, plasma deposition, propellant spray/air brushing, and so forth. At least some of these techniques are described in greater detail above, such as with respect to the vertically oriented component stack. Further, it will be understood that any suitable material as described herein may be used to form the external terminations of the plurality of interposers.

In addition to the first side surface and the second side surface, each component of the plurality of components may include a third side surface opposite a fourth side surface. The third side surface and the fourth side surface may extend from the first end surface to the second surface along the longitudinal direction and from the first side surface to the second side surface along the vertical direction. In some embodiments, the first external termination of at least one interposer of the plurality of interposers wraps around a first end of the interposer such that a first portion of the first external termination is formed on the first side surface, a second portion of the first external termination is formed on the first end surface, a third portion of the first external termination is formed on the third side surface, and a fourth portion of the first external termination is formed on the fourth side surface. In some embodiments, the second external termination of at least one interposer of the plurality of interposers wraps around a second end of the component such that a first portion of the second external termination is formed on the first side surface, a second portion of the second external termination is formed on the second end surface, a third portion of the second external termination is formed on the third side surface, and a fourth portion of the second external termination is formed on the fourth side surface.

In some embodiments, one or both of the first or second external terminations may partially wrap around the respective end of a respective interposer. For example, in some embodiments, the second portion of the first external termination and the second portion of the second external termination of each interposer of the plurality of interposers that wraps to the first end surface and the second end surface, respectively, is spaced apart from the third side surface and the fourth side surface along the lateral direction.

In embodiments including at least one interposer having a ground external termination disposed between the first and second external terminations, the ground external termination may wrap from the first side surface to one of the third side surface or the fourth side surface or both of the third side surface and the fourth side surface.

The vertically oriented interposer stack may include any suitable number of interposers and components stacked along the lateral direction. For example, in some embodiments, the vertically oriented interposer stack includes at least three components and at least four interposers stacked along the lateral direction, such as three, four, five, six, seven, or more components and four, five, six, seven, eight, or more interposers stacked along the lateral direction. In some embodiments, the vertically oriented interposer stack includes one more interposer than the number of components such that individual components are sandwiched between adjacent interposers. In other embodiments, more than one component may be sandwiched between adjacent interposers, and in still other embodiments, at least one component may not be sandwiched between adjacent interposers but may have an interposer on only one side of the component.

In some embodiments, as previously described, the vertically oriented interposer stack includes at least one filter. For example, at least one component of the plurality of components in the stack may be a filter. The at least one filter may be any suitable filter type, such as a thin-film filter or a multilayer filter, which thin-film or multilayer filter may be configured as described above, or the at least one filter may be any other suitable filter type. In some embodiments, the filter may include a signal path having an input and an output. The filter may be configured to filter signals from the input and produce a filtered output signal at the output. In some embodiments, a plurality of dielectric layers may have conductive layers formed thereon that are selectively shaped or patterned to form capacitors and/or inductors that, when stacked together, form the filter. However, rather than the input and output ports or external terminations being formed on the filter, the ports or terminations are formed on an interposer, and filter is disposed on the interposer to position the input and output of the filter in electrical connection with the input and output ports or terminations, respectively. Further, as described herein, the filter may be grounded through connection with a ground external termination formed on the interposer.

In some embodiments, one or more vias may be formed in a single component of the vertically oriented interposer stack, e.g., where a component of the stack is a filter, a via may be formed therein to connect two or more elements of the filter. In some embodiments, one or more vias may be formed to interconnect components within the vertically oriented interposer stack. For instance, a via formed in one component may contact a via formed in an adjacent component to electrically connect the adjacent components. In some embodiments, vias may extend through one or more interposers to electrically connect elements of the vertically oriented interposer stack. Suitable techniques and materials for forming vias in one or more components of the vertically oriented interposer stack are described more fully elsewhere herein, e.g., with respect to the vertical component stack described above.

The vertically oriented interposer stack may be configured for mounting on a mounting surface of a device to form an assembly, e.g., a vertically oriented interposer stack assembly. The assembly may include a device having a mounting surface, such as a printed circuit board (PCB) or the like, and a vertically oriented interposer stack such as described herein. The mounting surface may extend in a mounting plane that is parallel to an X-Y plane defined by the longitudinal direction and the lateral direction. The first side surface of each interposer of the plurality of interposers of the vertically oriented interposer stack may extend in a first plane parallel to the X-Y plane, and the vertically oriented interposer stack may be disposed on the mounting surface such that the first plane of each component of the plurality of components is parallel to the mounting plane. Further, the vertically oriented interposer stack may be disposed on the mounting surface such that the first side surface of each interposer of the plurality of interposers extends parallel to the mounting surface and the first external termination and the second external termination of each interposer of the plurality of interposers is in contact with the mounting surface.

As described herein, at least one external termination is disposed on the first side surface of each interposer of the vertically oriented interposer stack. For example, a first external termination, a second external termination, and a ground termination may each be formed on the first side surface of each interposer of the vertically oriented interposer stack. In some embodiments, when mounted on the mounting surface of the device, each external termination of the vertically oriented interposer stack may be in contact with a contact area on the mounting surface of the device, e.g., to electrically connect the vertically oriented interposer stack with the device.

In some embodiments, one or more components of the plurality of components of the vertically oriented interposer stack includes at least one internal conductive layer. The internal conductive layer may extend in the vertical direction and the longitudinal direction such that the internal conductive layer is perpendicular to the mounting surface when the stack is mounted on the mounting surface of the device. The internal conductive layer may be, for example, an inductor, an electrode of a capacitor, a patterned conductive line, etc.

In some embodiments, the contact area of the device is a plurality of separate contact areas, and the plurality of separate contact areas includes a separate contact area corresponding to a respective one external termination. For example, the plurality of separate contact areas may include a separate contact area corresponding to a respective one first external termination, second external termination, and ground termination of the plurality of interposers of the stack.

The assembly may also include one or more switches, e.g., fully or partially embedded in, or otherwise attached to or mounted on, the device and electrically connected to the plurality of components of the vertically oriented interposer stack. For instance, a switch of the device may be electrically connected to a respective one component of the plurality of components of the vertically oriented interposer stack, e.g., through at least one external termination of an interposer and the conductive pattern of the interposer, on which the respective one component can be disposed to electrically connect the respective one component and the conductive pattern. The one or more switches can allow selective enablement of components of the vertically oriented interposer stack. For example, the one or more switches may allow one or more components of the vertically oriented interposer stack to be selectively activated and deactivated, e.g., based on an operating frequency range, a desired performance characteristic, a power or other load, thermal or heat management, and/or other operational needs or goals.

The present disclosure also provides methods for forming a vertically oriented interposer stack such as described herein. The present disclosure may also provide methods for forming an assembly having a device and a vertically oriented interposer stack disposed thereon, as well be appreciated by those having ordinary skill in the art based on the present disclosure.

A method for forming a vertically oriented interposer stack may include depositing a conductive pattern on a surface of one or more interposers of a plurality of interposers. For example, the surface may be a third side surface of the one or more interposers, the third side surface extending in the longitudinal direction and the vertical direction. The conductive pattern may be formed from any suitable conductive material, such as those described herein, and the conductive pattern may be deposited on the one or more interposers using any suitable techniques, such as those described herein for depositing conductive material on a surface.

The method may also include forming a first external termination on a first side surface of one or more interposers of the plurality of interposers, the first side surface opposite a second side surface along the vertical direction and the first side surface and the second side surface each extending along the longitudinal direction from a first end surface to a second end surface that is opposite the first end surface along the longitudinal direction. The method may further include forming a second external termination on the first side surface of one or more interposers of the plurality of interposers. In some embodiments, the method can include forming a ground external termination on the first side surface of one or more interposers of the plurality of interposers. The ground external termination may be disposed between the first external termination and the second external termination along the lateral direction. It will be appreciated that forming the one or more external terminations (whether a first external termination, a second external termination, or a ground external termination) may include one or more of the techniques described above for forming external terminations, such as forming a solder fillet, wrapping a conductive material about the component such that the conductive material is disposed over two or more surfaces of the component, plating (e.g., electroless plating, FCT electroplating, etc.), forming breaks in a solid bar of termination material, sputtering, and/or any of the other techniques described herein.

The method may also include stacking the plurality of interposers along the lateral direction with one or more components disposed between adjacent interposers such that the first external terminations of the plurality of interposers are generally aligned with one another along the lateral direction and the second external terminations of the plurality of interposers are generally aligned with one another along the lateral direction. When components in the stack also include ground external terminations, the ground external terminations may be generally aligned with one another along the lateral direction.

### Example Embodiments

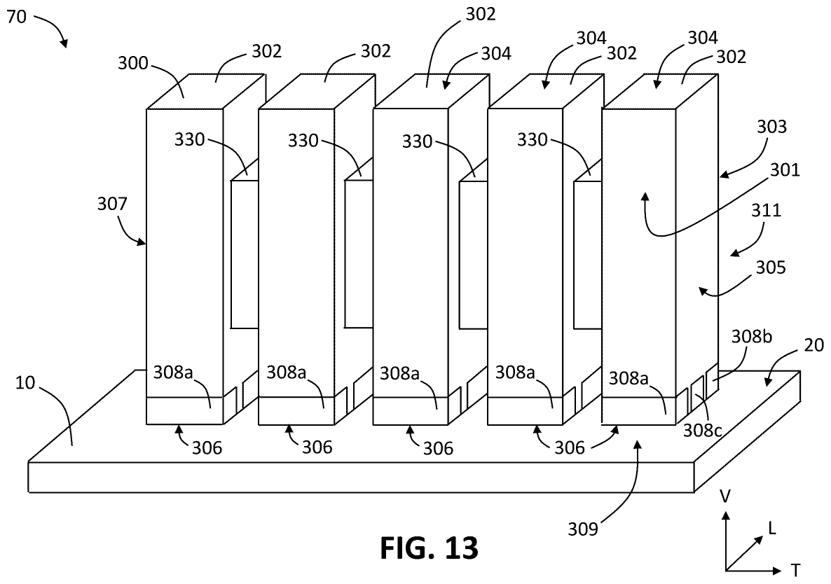

Referring now to FIGS. 13 through 15, example embodiments of the vertically oriented interposer stack, the vertically oriented interposer stack assembly, and methods for forming a vertically oriented interposer stack will be described in greater detail. It will be appreciated that the use of similar reference numerals as used with respect to the vertical component stack assembly 50, the vertically oriented component stack assembly, the vertical component stack 100, and the vertically oriented component stack 200 may denote the same or similar features.

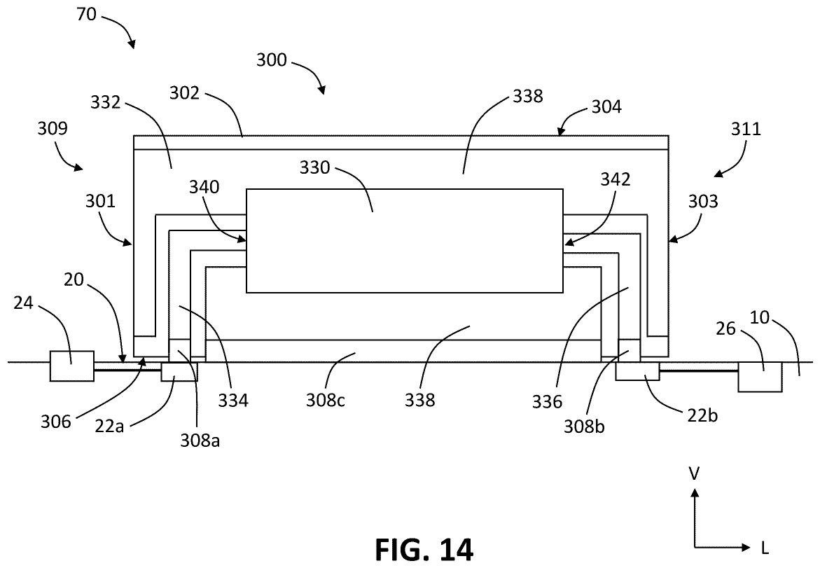

As illustrated in FIG. 13, which provides a schematic perspective view of a vertically oriented interposer stack assembly 70, the assembly 70 includes a vertically oriented interposer stack 300 disposed on a mounting surface 20 of a device 10. It will be appreciated that the device 10 may be a printed circuit board (PCB) or the like and may be configured as described above with respect to FIGS. 1 and 4. FIG. 14 provides a side view of the vertically oriented interposer stack assembly 70.

In the illustrated embodiment, the vertically oriented interposer stack 300 has five interposers 302 and four components 330 stacked along a lateral direction T, which is orthogonal to a longitudinal direction L and a vertical direction V. It will be appreciated that, in other embodiments, other numbers of interposers 302 and components 330 may be stacked together along the lateral direction T to form the vertically oriented interposer stack 300, which also may be referred to as a vertically oriented interposer bank. For example, three, five, six, or more interposers 302 may be stacked together with components 330 disposed therebetween to form the stack or bank 300.

Each interposer 302 includes a plurality of external terminations 308, including a first external termination 308a, a second external termination 308b, and a ground external termination 308c, which are all formed on a first side surface 306 of a respective interposer 302. That is, each external termination 308 of the interposers 302 of the vertically oriented interposer stack 300 is formed on the same side of a respective interposer 302. In the depicted embodiment, each external termination 308 is formed on the first side surface 306, which is opposite a second side surface 304 along the vertical direction V.

Each interposer 302 also defines a first end surface 301 opposite a second end surface 303 along the longitudinal direction L. The first side surface 306 and the second side surface 304 each extend along the longitudinal direction L from the first end surface 301 to the second end surface 303. Each interposer 302 further defines a third side surface 305 opposite a fourth side surface 307. The third side surface 305 and the fourth side surface 307 extend from the first end surface 301 to the second surface 303 along the longitudinal direction L and from the first side surface 306 to the second side surface 304 along the vertical direction V. The first side surface 306 and the second side surface 304 may further extend from the third side surface 305 to the fourth side surface 307 along the lateral direction T.

The vertically oriented interposer stack 300 may be disposed on the mounting surface 20 of the device 10 such that one or more of the interposers 302 are electrically connected to the device 10 as described herein. More particularly, as shown in FIGS. 13 and 14, the first side surface 306 is positioned in contact with the mounting surface 20 such that the first external termination 308a, the second external termination 308b, and the ground external termination 308c contact a contact area 22 (FIG. 14) of the device 10 to electrically connect the interposer 302 of the vertically oriented interposer stack 300 with the device 10. It will be appreciated that the contact area 22 may be any suitable material, such as a conductive material, for electrically connecting the interposers 302 and the device 10.

In some embodiments, the contact area 22 is a plurality of separate contact areas 22, such as the first contact area 22a and the second contact area 22b shown in FIG. 14. For instance, the plurality of separate contact areas 22 may include a separate contact area 22 corresponding to a respective one first external termination 308a, a respective one second external termination 308b, and a respective one ground external termination 308c of the plurality of interposers 302, e.g., each external termination 308 may contact a separate contact area 22. In other embodiments, multiple external terminations 308a, 308b, 308c may contact the same contact area 22, e.g., each first external termination 308a of the vertically oriented interposer stack 300 may connect with the same contact area 22.

The assembly 70 may also include one or more switches 24 or other device components 26, which may be fully or partially embedded in, or otherwise attached to or mounted on, the device 10 and electrically connected to one or more interposers 302 of the vertically oriented interposer stack 300. For instance, as shown in FIG. 14, a switch 24 of the device 10 may be electrically connected to a respective one interposer 302 of the vertically oriented interposer stack 300 through a contact area 22. Similarly, one or more device components 26, such as an external capacitor or resistor, an amplifier input, an antenna output, a microprocessor, etc., may be electrically connected to one or more interposers 302 of the vertically oriented interposer stack 300 through one or more contact areas 22.

Referring to FIG. 14, at least one interposer 302 of the plurality of interposers 302 can include a conductive pattern 332 deposited or formed on a surface of the interposer 302. For example, the conductive pattern 332 may be deposited or formed on the third side surface 305 of the interposer 302.

The conductive pattern 332 may have any suitable shape or configuration. In the depicted embodiment, the conductive pattern 332 includes an input line 334, an output line 336, and two ground portions 338. The conductive pattern may be formed from any suitable material and may be disposed on the surface 305 of the interposer 302 using any suitable technique or process.

In some embodiments, at least one component 330 in the vertically oriented interposer stack 300 is a filter. The at least one filter may be any suitable filter type, such as a thin-film filter or a multilayer filter, examples of which are illustrated in FIGS. 5A and 9A and FIGS. 5B and 9B, respectively. In some embodiments, the filter component 330 may be configured as shown FIG. 5A, 5B, 9A, or 9B. The filter component 330 may be positioned with respect to the third surface 305 of the interposer 302 such that an input of the filter is in electrical contact with the input line 334 of the conductive pattern 332 and an output of the filter is in electrical contact with the output line 336 of the conductive pattern 332. For example, the filter component 330 may be positioned such that a first end 340 of the filter component 330 contacts the input line 334 and a second end 342 of the filter component 330 contacts the output line 336, which can place the input and output of the filter component 330 in electrical connection with the input line 334 and the output line 336, respectively. As shown in FIG. 14, the filter component 330 also may be electrically connected to one or both of the ground portions 338.

It will be appreciated that each filter component 330 included in the vertically oriented interposer stack 300, as well as the conductive pattern 332 of one or more interposers 302, may be configured as needed based on, e.g., filter type (e.g., low-pass, high-pass, or passband), characteristic frequency (e.g., 6 GHz, 8 GHZ, 12 GHz, or a higher or a lower characteristic frequency), etc. Moreover, other types of components 330 may be included in the stack 300 as well, i.e., in at least some embodiments, a component 330 other than a filter may be disposed between adjacent interposers 302.

In some embodiments, the external terminations 308 of the interposers 302 in the stack 300 may be configured similar to the external terminations of the components 202 shown in FIGS. 7 and 10 (such as shown in FIG. 13) or similar to the external terminations of the components 202 shown in FIGS. 11A and 11B. For example, in some embodiments, the first external termination 308a of at least one interposer 302 of the stack 300 wraps around a first end 309 of the interposer 302 such that a first portion 308a-1 of the first external termination 308a is formed on the first side surface 306, a second portion 308a-2 of the first external termination 308a is formed on the first end surface 301, a third portion 308a-3 of the first external termination 308a is formed on the third side surface 305, and a fourth portion 308a-4 of the first external termination 308a is formed on the fourth side surface 307. Similarly, in some embodiments, the second external termination 308b of at least one interposer 302 of the stack 300 wraps around a second end 311 of the interposer 302 such that a first portion 308b-1 of the second external termination 308b is formed on the first side surface 306, a second portion 308b-2 of the second external termination 308b is formed on the second end surface 303, a third portion 308b-3 of the second external termination 308b is formed on the third side surface 305, and a fourth portion 308b-4 of the second external termination 308b is formed on the fourth side surface 307.

In other embodiments, at least one of the first or second external terminations 308a, 308b may partially wrap around the respective end 309, 311 of a respective interposer 302. For example, similar to the embodiment of FIG. 11A, the second portion 308a-2 of the first external termination 308a of each interposer 302 of the plurality of interposers that wraps to the first end surface 301 may be spaced apart from the third side surface 305 and the fourth side surface 307 along the lateral direction T. Further, similar to the embodiment depicted in FIG. 11B, the second portion 308b-2 of the second external termination 308b of each interposer 302 of the plurality of interposers that wraps to the second end surface 303 may be spaced apart from the third side surface 305 and the fourth side surface 307 along the lateral direction T.

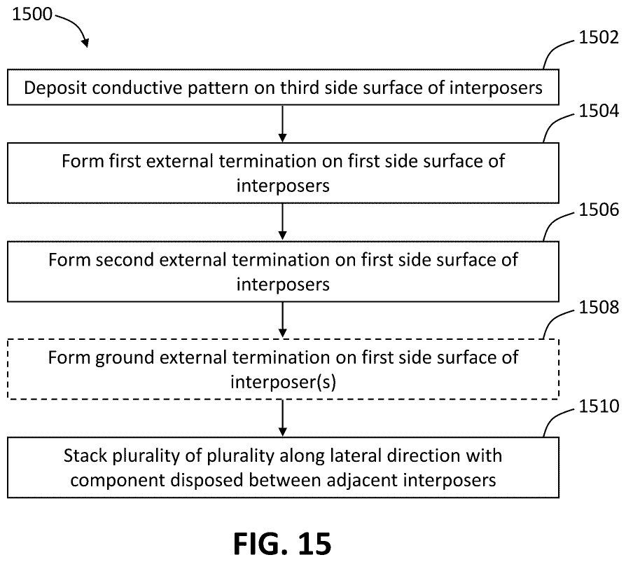

Turning to FIG. 15, an exemplary method 1500 for forming a vertically oriented interposer stack 300 includes (1502) depositing a conductive pattern 332 on a third side surface of each interposer of a plurality of interposers. The conductive pattern 332 may be formed from any suitable conductive material and may be formed using any suitable technique, such as those techniques described herein for depositing conductive material on a surface.

The method 1500 further includes (1504) forming a first external termination 308a on a first side surface 306 of the plurality of interposers 302. The method 1500 also includes (1506) forming a second external termination 308b on the first side surface 306 of the plurality of interposers 302. Optionally, the method 1500 includes (1508) forming a ground external termination 308c on the first side surface 306 of one or more of the plurality of interposers 302. As such, each external termination 308 (e.g., first external terminations 308a, second external terminations 308b, and, when formed on one or more components, ground external terminations 308c) formed on the plurality of interposers 302 is formed along the same edge or surface of the interposers 302.

As shown at (1510) in FIG. 15, the method 1500 also includes stacking the plurality of interposers 302 along a lateral direction T, with a respective one component 330 of a plurality of components 330 disposed between adjacent interposers 302. The stack of interposers 302 and components 330 forms the vertically oriented interposer stack 300, which may be disposed or mounted on a device 10 as described herein to form a vertically oriented interposer stack assembly 70. As described herein, the interposers 302 and the components 330 of the vertically oriented interposer stack 300 are oriented perpendicular to a mounting surface 20 of the device 10, rather than parallel to a mounting surface as components commonly are mounted on PCBs or the like, such that the interposers 302 and the components 330 are vertically oriented and the interposers 302 are terminated along one side of the stack 300. Such a vertically oriented interposer stack 300 can occupy less space on the device 10 than typical components, thus providing a space-saving advantage over known designs. Other advantages, such as improved performance, also may be realized from stacking the interposers 302, with components 330 sandwiched therebetween and in electrical contact with a conductive pattern formed on an adjacent interposer 302, into an interposer stack or bank 300 as described herein.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A vertically oriented interposer stack, the vertically oriented interposer stack defining a longitudinal direction, a lateral direction, and a vertical direction that are orthogonal to one another, the vertically oriented interposer stack comprising:
a plurality of interposers, each interposer of the plurality of interposers including a first side surface opposite a second side surface along the vertical direction and a first end surface opposite a second end surface along the longitudinal direction, the first side surface and the second side surface each extending along the longitudinal direction from the first end surface to the second end surface, and
a plurality of components, each component of the plurality of components disposed between adjacent interposers,
wherein each interposer of the plurality of interposer has a first external termination formed on the first side surface and a second external termination formed on the first side surface, the first external termination spaced apart from the second external termination along the longitudinal direction, and
wherein the plurality of interposers are stacked along the lateral direction such that the first external terminations of the plurality of interposers are generally aligned with one another along the lateral direction and the second external terminations of the plurality of interposers are generally aligned with one another along the lateral direction.

2. The vertically oriented interposer stack of claim 1, wherein at least one interposer of the plurality of interposers includes a conductive pattern formed on a third side surface of the at least one interposer, the third side surface extending along the longitudinal direction from the first end surface to the second end surface of the at least one interposer and extending along the vertical direction from the first side surface to the second side surface.

3. The vertically oriented interposer stack of claim 2, wherein at least one component of the plurality of components is a filter, and wherein the filter is disposed between the at least one interposer having the conductive pattern and an adjacent interposer such that the filter is in electrical contact with the conductive pattern.

4. The vertically oriented interposer stack of claim 3, wherein the conductive pattern includes an input line and an output line, and wherein the filter is disposed in electrical contact with the input line and the output line.

5. The vertically oriented interposer stack of claim 4, wherein the first external termination of the at least one interposer is an input port and the second external termination of the at least one interposer is an output port, and wherein the input line is connected with the input port and the output line is connected with the output port.

6. The vertically oriented interposer stack of claim 1, wherein at least one interposer of the plurality of interposers further comprises a ground external termination formed on the first side surface of the at least one interposer.

7. The vertically oriented interposer stack of claim 6, wherein the ground external termination is formed between the first external termination and the second external termination along the longitudinal direction.

8. The vertically oriented interposer stack of claim 1, wherein the vertically oriented interposer stack is configured for mounting on a mounting surface along the first side surface such that the first external termination and the second external termination of each interposer of the plurality of components is in contact with the mounting surface.

9. The vertically oriented interposer stack of claim 8, wherein each component of the plurality of components includes at least one internal conductive layer, the internal conductive layer extending in the vertical direction and the longitudinal direction such that the internal conductive layer is perpendicular to the mounting surface.

10. The vertically oriented interposer stack of claim 1, wherein:
each interposer of the plurality of interposers further comprises a third side surface opposite a fourth side surface, the third side surface and the fourth side surface extending from the first end surface to the second surface along the longitudinal direction and from the first side surface to the second side surface along the vertical direction,
the first external termination of each interposer of the plurality of interposers wraps around a first end of the interposer such that a first portion of the first external termination is formed on the first side surface, a second portion of the first external termination is formed on the first end surface, a third portion of the first external termination is formed on the third side surface, and a fourth portion of the first external termination is formed on the fourth side surface, and
the second external termination of each interposer of the plurality of interposers wraps around a second end of the interposer such that a first portion of the second external termination is formed on the first side surface, a second portion of the second external termination is formed on the second end surface, a third portion of the second external termination is formed on the third side surface, and a fourth portion of the second external termination is formed on the fourth side surface.

11. The vertically oriented interposer stack of claim 10, wherein the second portion of the first external termination and the second portion of the second external termination of each interposer of the plurality of interposers that wraps to the first end surface and the second end surface, respectively, is spaced apart from the third side surface and the fourth side surface along the lateral direction.

12. The vertically oriented interposer stack of claim 1, wherein at least one of the plurality of components is a filter.

13. The vertically oriented interposer stack of claim 12, wherein the first external termination is an input port of the filter and the second external termination is an output port of the filter, and wherein the filter further comprises a ground external termination disposed on the first side surface of the filter between the input port and the output port.

14. The vertically oriented interposer stack of claim 12, wherein the filter is a thin-film filter.

15. The vertically oriented interposer stack of claim 12, wherein the filter is a multilayer filter.

16. The vertically oriented interposer stack of claim 1, wherein each interposer of the plurality of interposers includes a substrate comprising aluminum.

17. An assembly, comprising:
a device having a mounting surface; and
a vertically oriented interposer stack, the vertically oriented interposer stack defining a longitudinal direction, a lateral direction, and a vertical direction that are orthogonal to one another, the vertically oriented interposer stack comprising:
a plurality of interposers, each interposer of the plurality of interposers including a first side surface opposite a second side surface along the vertical direction and a first end surface opposite a second end surface along the longitudinal direction, the first side surface and the second side surface each extending along the longitudinal direction from the first end surface to the second end surface, and
a plurality of components, each component of the plurality of components disposed between adjacent interposers,
wherein each interposer of the plurality of interposer has a first external termination formed on the first side surface and a second external termination formed on the first side surface, the first external termination spaced apart from the second external termination along the longitudinal direction, and
wherein the plurality of interposers are stacked along the lateral direction such that the first external terminations of the plurality of interposers are generally aligned with one another along the lateral direction and the second external terminations of the plurality of interposers are generally aligned with one another along the lateral direction, and
wherein the vertically oriented interposer stack is disposed on the mounting surface along the first side surface such that the first external termination and the second external termination of each interposer of the plurality of interposers is in contact with the mounting surface.

18. The assembly of claim 17, wherein at least one interposer of the plurality of interposers includes a conductive pattern formed on a third side surface of the at least one interposer, the third side surface extending along the longitudinal direction from the first end surface to the second end surface of the at least one interposer and extending along the vertical direction from the first side surface to the second side surface.

19. The assembly of claim 18, wherein at least one component of the plurality of components is a filter, and wherein the filter is disposed between the at least one interposer having the conductive pattern and an adjacent interposer such that the filter is in electrical contact with the conductive pattern.

20. The assembly of claim 19, wherein the conductive pattern includes an input line and an output line, and wherein the filter is disposed in electrical contact with the input line and the output line.

21. The assembly of claim 20, wherein the first external termination of the at least one interposer is an input port and the second external termination of the at least one interposer is an output port, and wherein the input line is connected with the input port and the output line is connected with the output port.

22. The assembly of claim 17, wherein each component of the plurality of components includes at least one internal conductive layer, the internal conductive layer extending in the vertical direction and the longitudinal direction such that the internal conductive layer is perpendicular to the mounting surface of the device.

23. The assembly of claim 17, wherein at least one of the plurality of components is a filter.

24. The assembly of claim 23, wherein the first external termination is an input port of the filter and the second external termination is an output port of the filter, and wherein the filter further comprises a ground external termination formed on the first side surface of the filter between the input port and the output port.

25. The assembly of claim 17, wherein the device comprises at least one switch in electrical contact with at least one component of the plurality of components of the vertically oriented interposer stack.

26. The assembly of claim 17, wherein the first external termination and the second external termination of each interposer of the plurality of interposers are in contact with a contact area on the mounting surface of the device.

27. The assembly of claim 26, wherein the contact area is a plurality of separate contact areas, and wherein the plurality of separate contact areas includes a separate contact area corresponding to a respective one first external termination and second external termination of each interposer of the plurality of interposers.

28. A method for forming a vertically oriented interposer stack, the vertically oriented interposer stack defining a longitudinal direction, a lateral direction, and a vertical direction that are orthogonal to one another, the method comprising:
forming a first external termination on a first side surface of each interposer of a plurality of interposers, the first side surface opposite a second side surface along the vertical direction and the first side surface and the second side surface each extending along the longitudinal direction from a first end surface to a second end surface that is opposite the first end surface along the longitudinal direction;
forming a second external termination on the first side surface of each interposer of a plurality of interposers; and
stacking the plurality of interposers along the lateral direction with a respective one component of a plurality of components disposed between each adjacent pair of interposers of the plurality of interposers, the plurality of interposers stacked along the lateral direction such that the first external terminations of the plurality of interposers are generally aligned with one another along the lateral direction and the second external terminations of the plurality of interposers are generally aligned with one another along the lateral direction.
